(19) United States
(12) Patent Application Publication
(10) Pub. No.: US 2012/0070958 A1
(43) Pub. Date: Mar. 22, 2012

(54) METHOD OF MANUFACTURING SEMICONDUCTOR DEVICE

(75) Inventors: Kazuyoshi Furukawa, Kanagawa-ken (JP); Yoshinori Natsume, Kanagawa-ken (JP); Yasuhiko Akaike, Fukuoka-ken (JP); Shinji Nunotani, Fukuoka-ken (JP); Wakana Nishiwaki, Kanagawa-ken (JP); Masaaki Ogawa, Kanagawa-ken (JP); Toru Kita, Chiba-ken (JP); Hidefumi Yasuda, Kanagawa-ken (JP)

(73) Assignee: KABUSHIKI KAISHA TOSHIBA, Tokyo (JP)

(21) Appl. No.: 13/238,715

(22) Filed: Sep. 21, 2011

(30) Foreign Application Priority Data
Sep. 22, 2010 (JP) P2010-212567
Sep. 13, 2011 (JP) P2011-200033

(51) Int. Cl. H01L 21/762

(52) U.S. Cl. 438/455; 257/E21.567

(57) ABSTRACT

In a method of manufacturing a semiconductor device of an embodiment, at room temperature, a first substrate including a semiconductor laminate body is adhered to a second substrate with a smaller thermal expansion coefficient than that of the first substrate. Then, the first substrate and the second substrate are heated with the first substrate heated at a temperature higher than that of the second substrate. Thus the first substrate and the second substrate are bonded together. The first substrate is either a sapphire substrate including a nitride-based semiconductor layer, or a GaAs substrate including a phosphorus-based semiconductor layer. The second substrate is a silicon substrate, a GaAs substrate, a Ge substrate, or a metal substrate.

### CROSS-REFERENCE TO RELATED APPLICATIONS

This application is based upon and claims the benefit of priority from the prior Japanese Patent Application No. 2010-212567, filed on Sep. 22, 2010, and No. 2011-200033, filed on Sep. 13, 2011; the entire contents of which are incorporated herein by reference.

### FIELD

Embodiments of the present invention relate to a method of manufacturing a semiconductor device.

### BACKGROUND

Conventional methods of manufacturing a semiconductor device include a process of bonding two substrates of the same kind or different kinds together. There are various methods of bonding two substrates. Among them, methods commonly employed include a process of heat treatment. For example, in the case of using a bonding material such as a metal, solder, or glass frit, two substrates to be bonded are firstly heated to melt or soften the bonding material at the bonded interface between the two surfaces, thereby the two substrates are bonded together, and then the substrates are cooled down to the room temperature.

On the other hand, in the case of using no bonding material, a method called direct bonding and another method called surface activated bonding are employed.

The direct bonding is a method where two substrates are firstly brought into close contact with each other at room temperature by the bonding force of OH-groups, the two substrates are firmly bonded together with the bonding reaction at the interface advanced with a temperature rise of the two substrates, and lastly the two substrates are cooled down to the room temperature.

The surface activated bonding is a technique where the surfaces of the substrates in a vacuum are firstly subjected to an activating treatment, such as a plasma-treatment process or a sputtering process, to remove the contamination and the natural oxide on the surfaces, or to form dangling bonds on the surfaces, and then the two substrates are bonded together only by bringing the activated surfaces into contact with each other at room temperature. The bonding of the two substrates at room temperature may be followed by a heat-treatment process to increase the bonding strength.

If two substrates made of different materials are bonded together by such conventional methods, the difference in the thermal expansion coefficient between the two substrates sometimes causes a problem in the substrates. To be specific, when the temperature of the two substrates is raised or lowered, the substrate with a larger thermal expansion coefficient expands or shrinks more than the one with a smaller thermal expansion coefficient. A thermal stress acts on the bonded interface and the substrates. As a consequence, the two substrates may be separated from each other, or the substrates themselves may be warped or broken during or after the bonding process.

### BRIEF DESCRIPTION OF THE DRAWINGS

FIG. 1 is a schematic sectional view illustrating a semiconductor device for a method of manufacturing a semiconductor device according to a first embodiment.

FIGS. 2A to 2E show schematic sectional views illustrating processes of manufacturing a semiconductor device according to the first embodiment.

FIG. 3 is a schematic sectional view illustrating a process of bonding and pressure-bonding two substrates together according to the first embodiment.

FIGS. 4A and 4B show graphs related to the first embodiment and illustrating the conditions of the time and the temperature related to the bonding and the pressure-bonding method. FIG. 4A illustrates the time-temperature conditions according to the first embodiment. FIG. 4B illustrates the time-temperature conditions according to a first comparative example.

FIGS. 5A to 5E show schematic sectional views illustrating processes of manufacturing a semiconductor device according to a first modified example of the first embodiment.

FIG. 6 is a graph illustrating the conditions of the time and the temperature related to the bonding and the pressure-bonding method according to the first modified example of the first embodiment.

FIG. 7 is a schematic sectional view illustrating a semiconductor device for a method of manufacturing a semiconductor device according to a second embodiment.

FIGS. 8A to 8D show schematic sectional views illustrating processes of manufacturing a semiconductor device according to the second embodiment.

FIG. 9 is a schematic sectional view illustrating a process of bonding and pressure-bonding two substrates together according to the second to fourth embodiments.

FIGS. 10A and 10B show graphs related to the second embodiment as well as a second comparative example, and illustrating the conditions of the time and the temperature related to the bonding and the pressure-bonding method. FIG. 10A illustrates the time-temperature conditions according to the second embodiment. FIG. 10B illustrates the time-temperature conditions according to the second comparative example.

FIGS. 11A to 11C show graphs illustrating the conditions of the time and the temperature for the boding method according to modified examples of the second embodiment. FIG. 11A illustrates the time-temperature conditions according to a first modified example of the second embodiment. FIG. 11B illustrates the time-temperature conditions according to a second modified example. FIG. 11C illustrates the time-temperature conditions according to a third modified example.

FIG. 12 is a schematic sectional view illustrating a semiconductor device for a method of manufacturing a semiconductor device according to a third embodiment.

FIGS. 13A to 13E show schematic sectional views illustrating processes of manufacturing a semiconductor device according to the third embodiment.

FIGS. 14A and 14B show graphs illustrating the conditions of the time and the temperature for the boding method according to the third embodiment. FIG. 14A illustrates the time-temperature conditions according to the third embodiment.

FIG. 14B illustrates the time-temperature conditions according to a first modified example of the third embodiment.

FIG. 15 is a schematic sectional view illustrating a semiconductor device 500 according to a fourth embodiment.

FIG. 16 is a graph illustrating the conditions of the time and the temperature for the bonding method according to the fourth embodiment.

### DETAILED DESCRIPTION

A method of manufacturing a semiconductor device according to an embodiment includes: forming a first substrate, providing a semiconductor laminate body to support substrate, adhering a second substrate to a surface of the first substrate in which the semiconductor laminate body, the second substrate having the second substrate having a thermal expansion coefficient different from the thermal expansion coefficient of the first substrate; and bonding the first substrate and the second substrate by heating the first and second substrates while one of the substrates with a smaller thermal expansion coefficient is heated at a higher temperature than that of the other substrate.

Some embodiments of the present invention are described below by referring to the drawings.

The term “bonding” means an act of forming two substrates into a single body by putting together directly or with a bonding layer interposed therebetween. If an act of bonding two substrates together is accompanied by a heat treatment within the scope of the present invention, the heat-treatment process is considered to be a part of the bonding process.

The term “adhering” means a state where two substrates to be bonded together are held together by bringing the entire bonding surfaces of the two substrates into contact with each other by external forces or their own forces.

In addition, the term “InGaAlP-based” body means a semiconductor laminate body made of a material represented by a composition formula Inₓ(Ga1-_{y}Al_{y})1-ₓP (0<x<1, 0≦y≦1).

### First Embodiment

The first embodiment relates to a eutectic bonding method in which two substrates with different thermal expansion coefficients are bonded together by using a eutectic metal.

A specific description will be given below of a eutectic bonding method in which a silicon substrate and a substrate obtained by growing a GaN epitaxial layer on a sapphire substrate are prepared and the two substrates are bonded together by using a eutectic metal. However, substrates usable for this embodiment are not limited to the substrates as described above. For example, the embodiment is also applicable to a method of bonding a Si substrate to a substrate obtained by epitaxially growing an InGaAlP-based layer on a GaAs substrate.

Moreover, in the following explanation as an example, although the semiconductor device with which the p type a semiconductor laminate body was formed in the n type substrate is raised, it is applicable to the p type substrate also to the semiconductor device with which the n type semiconductor laminate body was formed.

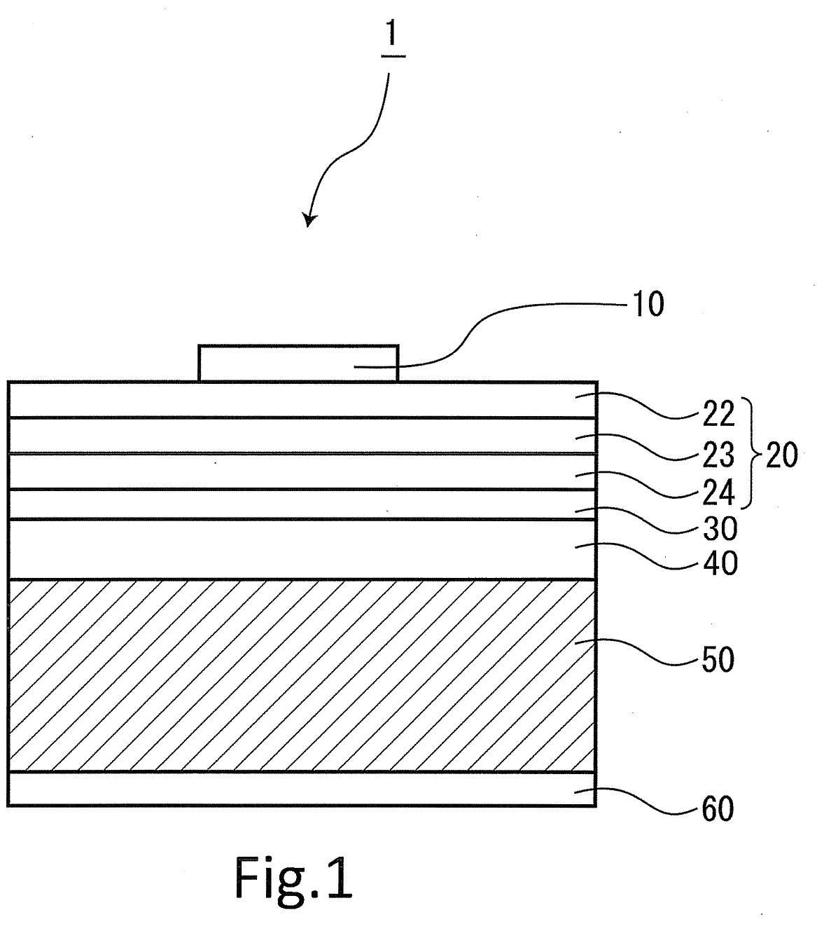

FIG. 1 is a schematic sectional view illustrating a semiconductor device 1 for a method of manufacturing a semiconductor according to the first embodiment. As FIG. 1 shows, the semiconductor device 1 is, for example, a GaN-based LED.

The semiconductor device 1 includes, from above, an upper electrode 10, a semiconductor laminate body 20, a reflective layer 30, a bonding layer 40, a Si substrate 50, and a lower electrode 60.

The semiconductor laminate body 20 has a first principal surface and a second principal surface. The upper electrode 10 is provided on the first-principal-surface side. The reflective layer 30 and the bonding layer 40 are provided on the second-principal-surface side. The Si substrate 50 and the lower electrode 60 are also provided on the second-principal-surface side with the reflective layer 30 and the bonding layer 40 interposed therebetween.

The semiconductor laminate body 20 is formed by epitaxially growing a gallium-nitride (GaN)-based compound semiconductor layer on an unillustrated sapphire substrate used as a substrate for growth. To be specific, the semiconductor laminate body 20 includes an n-type clad layer 22 located on the first-principal-surface side, a p-type clad layer 24 located on the second-principal-surface side, and an active layer 23 located in the middle, all of which are laminated with one another. For the purpose of diffusing currents and making contact with electrodes, the semiconductor laminate body 20 includes plural layers including a GaN-based semiconductor layer containing In and Al as needed.

The active layer 23 may have a DH (double hetero) MQW (multiple-quantum well) structure, for example. The active layer 23 is sandwiched by the n-type clad layer 22 and the p-type clad layer 24 from both sides, and thereby traps the carriers in the vertical direction.

The semiconductor laminate body 20 may include a contact layer (not illustrated) to make contact with the upper electrode 10, and may include a transparent conductive film (not illustrated) to improve the luminance. The reflective layer 30 is provided on the second-principal-surface side of the semiconductor laminate body 20 with a barrier layer interposed therebetween. The reflective layer 30 may be made of a metal, such as silver (Ag) with a high reflectance, gold (Au) serving also as a bonding layer, and aluminum (Al). Alternatively, the reflective layer 30 may be made of an alloy mainly containing any of the above-mentioned metals. Note that a barrier layer (not illustrated) mainly containing Ti, Ni, W, Pt, or the like may be provided between the semiconductor laminate body 20 and the reflective layer 30.

The reflective layer 30 may be provided only on a portion requiring reflection (not illustrated). For example, it is possible to bond the semiconductor laminate body 20 and the Si substrate 50 by providing a reflective film 30 only on a central portion in the second principal surface of the semiconductor laminate body 20, and providing no reflective film 30 provided on peripheral portions in the second principal surface of the semiconductor laminate body 20. Even in this way, the adhesion strength does not vary because reflective films generally have low adhesion properties to the adjacent films or substrates. On the other hand, it is possible to increase the bonding strength between the semiconductor laminate body 20 and the Si substrate 50 while maintaining the optical reflectance. Moreover, with such a structure, it is possible to dice chips without exposing the reflective layer 30, which is weak mechanically and chemically. Accordingly, the yield in the blade dicing process can be improved and the chips thus fabricated can be made more reliable.

The bonding layer 40 is provided on the opposite side of the reflective layer 30 to the one where the semiconductor laminate body 20 is provided, or the bonding layer 40 is provided on the second-principal-surface side of the semiconductor laminate body 20. For the sake of descriptive convenience, the bonding layer 40 of this embodiment is made of a gold-tin (AuSn) material with the gold (Au) as the main constituent. Alternatively, the bonding layer 40 may be made of a gold-indium (AuIn) material (melting point of In: 156° C.), a gold-germanium (AuGe) material (eutectic temperature: 350° C.), a gold-silicon (AuSi) material (eutectic temperature: approximately 380° C.), or something similar.

The Si substrate 50 has a first principal surface and a second principal surface. The Si substrate 50 is provided on the second-principal-surface side of the semiconductor laminate body 20 with the first principal surface of the Si substrate 50 being in contact with the bonding layer 40. The Si substrate 50 may be, for example, a boron (B) doped, high-concentration p-type substrate with a specific resistance of 1 to 20 mΩ·cm. The substrate 50 may have a size of 4 inches and a thickness of 300 μm. The Si substrate 50 is preferably a high-concentration, low-resistance substrate because electric current is supplied from the lower electrode 60 to the light-emitting layer through the Si substrate 50. In addition, the Si substrate 50 may be an n-type substrate.

The lower electrode 60 is provided on the second-principal-surface side of the Si substrate 50.

As has been described thus far, the semiconductor device 1 of this embodiment includes the semiconductor laminate body 20 with a GaN-based composition and the reflective layer 30, so that the semiconductor device 1 can emit light with a high luminance.

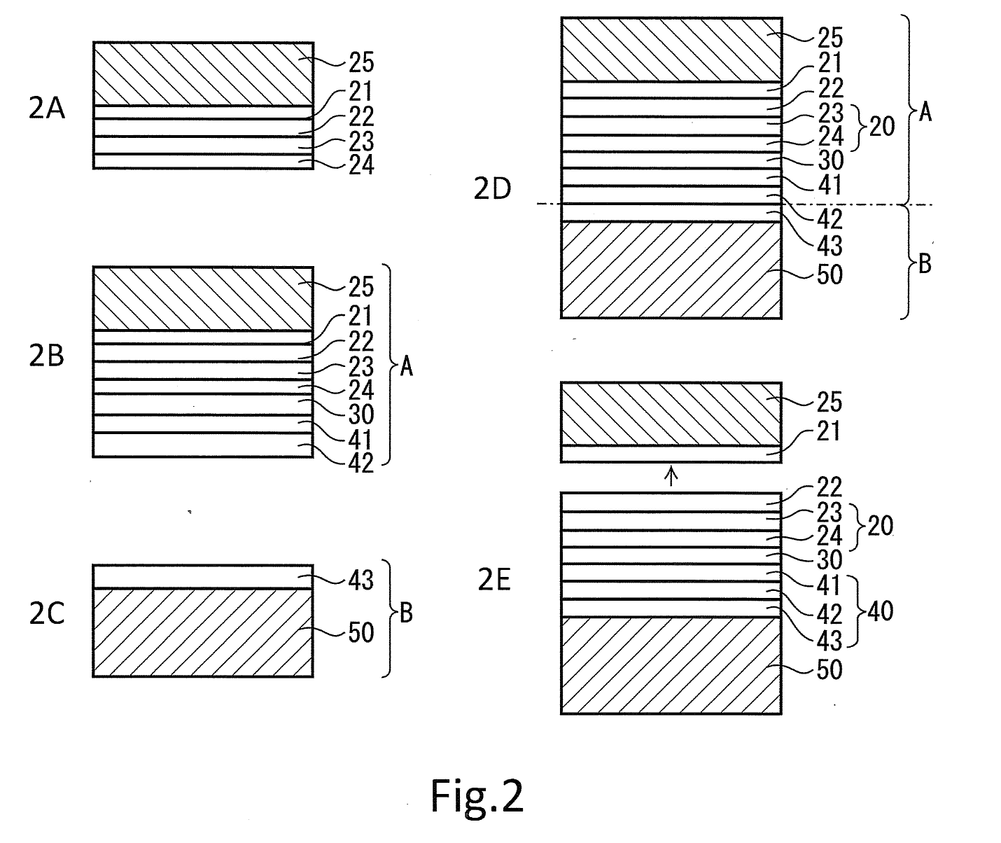

FIGS. 2A to 2E show schematic sectional views illustrating processes of manufacturing the semiconductor device 1 according to this embodiment.

As FIG. 2A shows, the semiconductor laminate body 20 is firstly formed by epitaxial growth of GaN material on a sapphire substrate 25 (thermal expansion coefficient=7.0×10⁻⁶/K). The semiconductor laminate body 20 includes a low-temperature-grown GaN buffer layer 21, an n-type GaN clad layer 22, a GaN/InGaN, MQW (multiple quantum well) active layer 23, a p-type GaN clad layer 24, which are provided in this order from the side of the sapphire substrate 25. The semiconductor laminate body 20 is formed, for example, by using an epitaxial-growth apparatus such as an MOCVD (metal organic chemical vapor deposition) apparatus. In addition, the above-described laminate structure is not the only possible structure of the semiconductor laminate body 20. For example, the active layer may have only a single InGaN layer. The clad layer may have a structure including two or more layers with different compositions or carrier concentrations. The semiconductor laminate body 20 may have additional layers other than the above-mentioned ones if such additional layers are necessary for the design of the semiconductor laminate body 20.

Then, as FIG. 2B shows, the reflective layer 30 is formed on the second-principal-surface side of the semiconductor laminate body 20. The reflective layer 30 preferably has a thickness of, for example, 50 nm or more because such a thickness helps keep the reflectance at a high level. Nevertheless, if the reflective layer 30 is too thick, a larger stress acts between the reflective layer 30 and the semiconductor laminate body 20. In addition, a thicker reflective layer 30 means more cost. Accordingly, the thickness of the reflective layer 30 is preferably not larger than 1 μm. If the reflective layer 30 is made mainly of Ag, the reflective layer 30 can be patterned by either an etching method using a solution containing phosphoric acid or a dry etching method. Note that the reflective layer 30 may be firstly formed on the entire second principal surface of the semiconductor laminate body 20, and then the reflective layer 30 may be patterned using a photoresist so that the reflective layer 30 is provided partially on the second principal surface of the semiconductor laminate body 20.

Then, a first bonding layer 41 is formed on the reflective layer 30. The first bonding layer 41 is made, for example, mainly of Au. The first bonding layer 41 preferably has a thickness ranging from 0.1 to 10 μm. The thickness of the first bonding layer 41 of this embodiment is assumed to be 1 μm for the sake of descriptive convenience.

Then, a second bonding layer 42 is formed on the first bonding layer 41. The second bonding layer 42 of this embodiment is assumed to be made of a material with a composition Au0.28Sn0.72 (eutectic temperature: approximately 280° C.) for the sake of descriptive convenience. It is, however, allowable that the second bonding layer 42 is made of a metal such as In, Si, and Sn that form low-melting-point alloys with Au. Alternatively, the second bonding layer 42 may be made of an alloy or a mixture of any of the above-mentioned metals with Au, or may be made by combining some of the metals, the alloys, and the mixtures. The second bonding layer 42 preferably has a thickness ranging from 0.1 to 10 μm. In the following description, the thickness of the second bonding layer 42 is assumed to be 0.8 μm for the sake of descriptive convenience.

Hereinbelow, a term “first substrate A” is used to mention the substrate in a state where the semiconductor laminate body 20, the reflective layer 30, the first bonding layer 41, and the second bonding layer 42 are formed on and above the sapphire substrate 25.

On the other hand, as FIG. 2C shows, a third bonding layer 43 made, for example, mainly of Au is formed on the Si substrate 50 (thermal expansion coefficient=4.2×10⁻⁶/K). The third bonding layer 43 preferably has a thickness ranging from 0.1 to 10 μm. The third bonding layer 43 of this embodiment is assumed to have a thickness of 1 μm for the sake of descriptive convenience.

Hereinbelow, a term “second substrate B” is used to mention a substrate in a state where the third bonding layer 43 is formed on the Si substrate 50 for the sake of descriptive convenience.

Then, as FIG. 2D shows, the first substrate A and the second substrate B are held together with the second bonding layer 42 of the first substrate A and the third bonding layer 43 of the second substrate B being placed one upon the other. The first substrate A and the second substrate B are then bonded together by being pressurized and heated up to or higher than the melting point of the second bonding layer 42. Alternatively, the first substrate A and the second substrate B may be heated up to or higher than the melting temperature of the second bonding layer 42 and either the first bonding layer 41 or the third bonding layer 43. The bonding temperature may be within a temperature range, for example, from 80 to 600° C. depending upon the materials that the bonding layers 41 to 43 are made of. Melted bonding layers fill the gap between the second bonding layer 42 and the third bonding layer 43 caused by surface loughness if the bonding surfaces are flat as shown in FIG. 2. In addition, if the reflective layer 30 is provided partially on the second principal surface of the semiconductor laminate body 20, the melted bonding layers fill the level difference between the portions where the reflective layer 30 is provided and the portions where no reflective layer 30 is formed. Thus, the bonding strength between the first substrate A and the second substrate B can be improved.

Under some conditions of time and temperature in the bonding process, alloying is likely to progress from the vicinity of the interface between the first bonding layer 41 and the third bonding layer 43. By changing the temperature and time for the heat-treatment process, the composition ratio of the alloy thus produced can be controlled. Consequently, the bonding strength between the first bonding layer 41 and the third bonding layer 43 can be improved.

Lastly, as FIG. 2E shows, the sapphire substrate 25 which is a substrate for crystal growth is removed. For example, a technique known as the laser-lift-off method may be used in which laser light is applied onto the low-temperature-grown GaN buffer layer 21 from the sapphire substrate 25 side so that the sapphire substrate 25 is removed by decomposing the low-temperature-grown GaN buffer layer 21.

Alternatively, a technique known as the chemical-lift-off method may be used in which a chemically weak film is firstly formed between the sapphire substrate 25 and the semiconductor laminate body 20 and then the sapphire substrate 25 is removed by chemically etching this film.

After that, the upper electrode 10 is formed on the first principal surface of the semiconductor laminate body 20, and the lower electrode 60 is formed on the opposite surface of the Si substrate 50 to the bonded interface between the bonding layer 40 and the Si substrate 50. Thus it is possible to obtain the semiconductor device 1 shown in FIG. 1.

Note that, in this embodiment, the first substrate A and the second substrate B are bonded together after the second bonding layer 42 is provided in the first substrate A. However, the second bonding layer 42 may be provided only in the second substrate B, or both in the first substrate A and the second substrate B.

In addition, the metals to be used for the reflective layer 30 and the bonding layer 40, e.g. Ag, Au, Sn, In, Si, Sn, and other metals, are likely to react with each other or with Si and the GaN-based epitaxial film included in the substrates. Accordingly, although not illustrated, layers known as barrier layers are preferably provided between the GaN-based epitaxial film and the reflective film 30, between the reflective film 30 and the first bonding layer 41, and between the third bonding layer 43 and the Si substrate 50 so as to prevent the diffusion and the alloying reaction. For example, a high-melting-point metal, e.g. Ti, W, Pt, and Ni, or an alloy of some of these metals are generally used to form the barrier layers. In addition, some of the above-mentioned metals may be combined together, or layers of these metals may be repeatedly formed as needed.

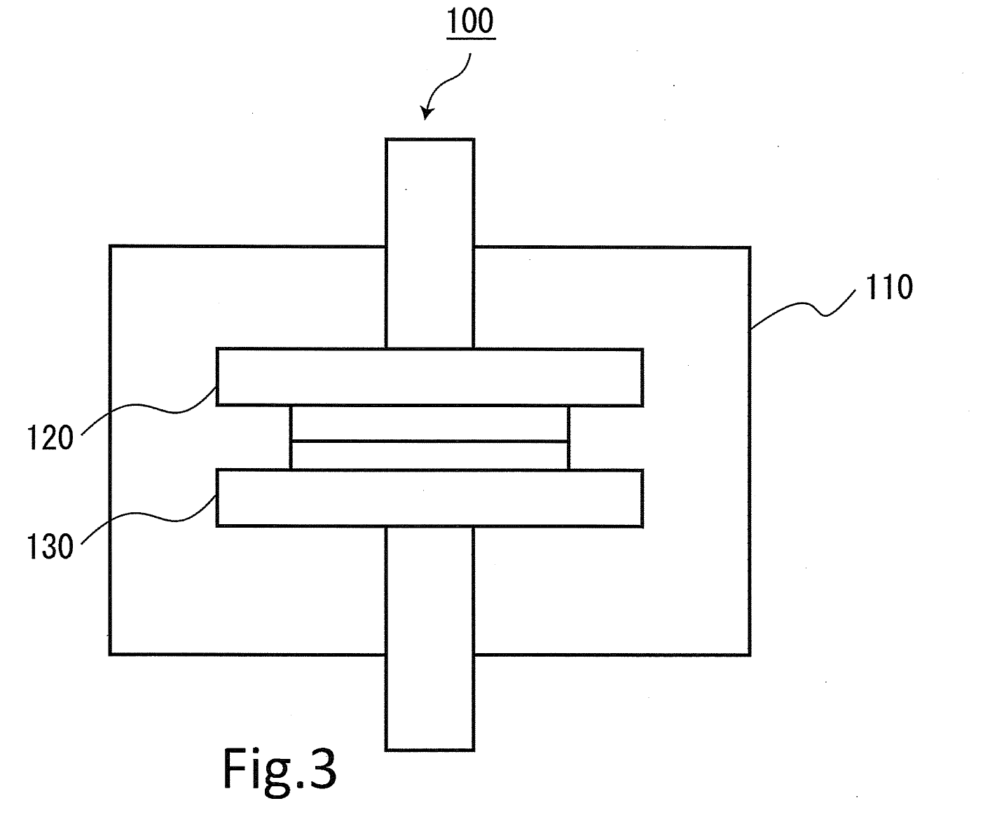

FIG. 3 is a schematic sectional view illustrating a process of bonding the first substrate A and the second substrate B by using a heater apparatus 100. The heater apparatus 100 includes a vacuum chamber 110, an upper heater plate 120, and a lower heater plate 130. The vacuum chamber 110 can set its atmosphere to be a vacuum atmosphere, a reduced-pressure atmosphere, or an inert-gas atmosphere. In addition, the heater apparatus 100 has a function to control individually the temperature of the upper heater plate 120 and the temperature of the lower heater plate 130. Moreover, the heater apparatus 100 has a mechanism (not illustrated) to apply a load, up to approximately 10 tons, to the substrates interposed between the upper heater plate 120 and the lower heater plate 130.

In this embodiment, the first substrate A is fixed to the upper heater plate 120 by an electrostatic force. The second substrate B, on the other hand, is fixed to the lower heater plate 130 by an electrostatic force. Then, in a vacuum atmosphere, both the upper heater plate 120 and the lower heater plate 130 are made to work, and thereby the bonding layers 42 and 43 of the two substrates A and B are adhered to each other. After that, the two substrates A and B are pressurized with a load P by the two heater plates 120 and 130 placed to face each other. In this embodiment, the load P may be a load of 500 kg, for example.

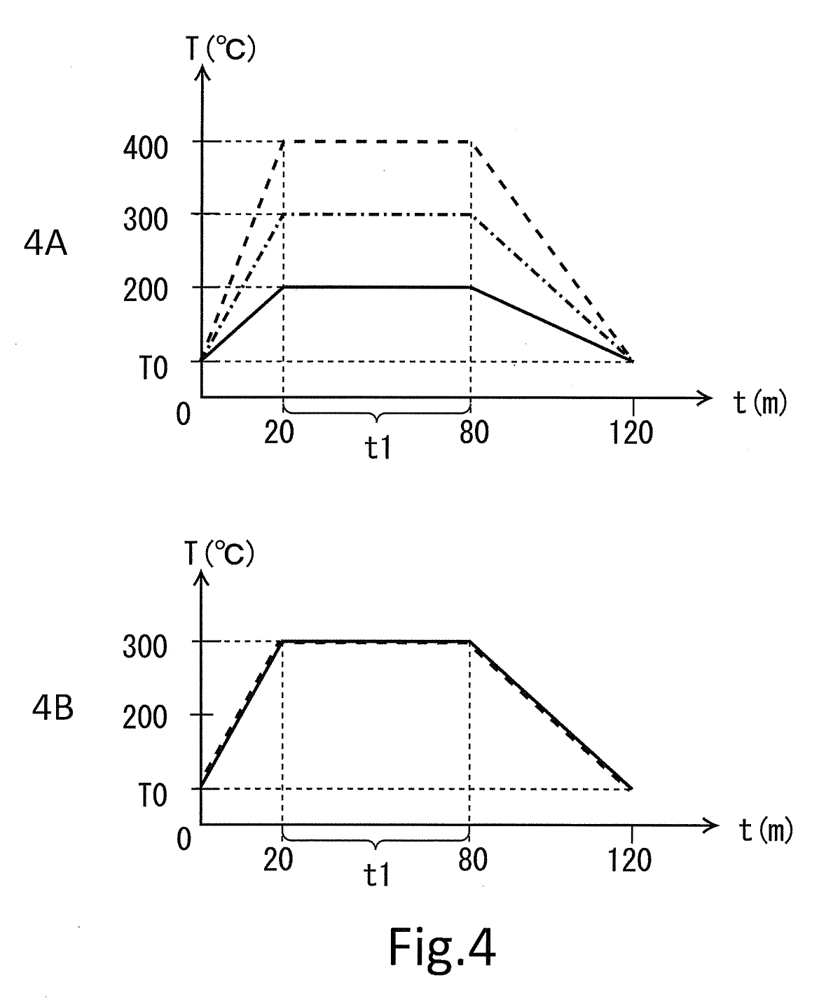

FIGS. 4A and 4B show graphs illustrating conditions of time and temperature related to the bonding method of this embodiment. The horizontal axis of each graph represents the time t (min), and the vertical axis represents the temperature T (° C.). The solid lines represent the time/temperature of the upper heater plate 120, the dashed lines represent the time/temperature of the lower heater plate 130, and the dashed-dotted lines represent the average of the time/temperature of the two heater plates 120 and 130.

In this embodiment, as FIG. 4A shows, the upper heater plate 120 where the first substrate A including the sapphire substrate 25 with a thermal expansion coefficient of 7.0×10⁻⁶/K is mounted is heated under some conditions of temperature and time, while the lower heater plate 130 where the second substrate B including the Si substrate 50 with a thermal expansion coefficient of 4.2×10⁻⁶/K is heated under different conditions of temperature and time.

The temperature of the upper heater plate 120 is raised from the room temperature T0 up to 200° C. in 20 minutes, then is kept at 200° C. for a keeping time t1 of 60 minutes, and then is lowered from 200° C. down to the room temperature T0 in 40 minutes. In the meanwhile, the temperature of the lower heater plate 130 is raised from the room temperature T0 up to 400° C. in 20 minutes, then is kept at 400° C. for a keeping time t1 of 60 minutes, and then is lowered from 400° C. down to the room temperature T0 in 40 minutes.

Assuming that the two substrates have the same thickness, and that the temperature of each substrate to be bonded changes linearly in a direction that is normal to the principal surfaces of the substrate, the temperature represented by the dashed-dotted line showing the average temperature of the temperature set for the upper heater plate 120 and the temperature set for the lower heater plate 130 corresponds to the temperature at the bonded interface between the first substrate A and the second substrate B. Once the heating is started and the temperature at the bonded interface reaches 280° C. (i.e. the eutectic point of Au_{0.28}Sn_{0.72}) the second bonding layer 42 made of an Au_{0.28}Sn_{0.72} material becomes eutectic and is thus melted, and then the melted second bonding layer 42 becomes incorporated into the first bonding layer 41 and the third bonding layer 43. After the temperatures of the two heater plates 120 and 130 are kept for 60 minutes, the temperatures of the two heater plates 120 and 130 are lowered down. Hence, the melted AuSn content of the second bonding layer 42 is solidified while the temperatures are being lowered. Consequently, the two substrates A and B are bonded together at the bonded interface of the bonding layers as shown in FIG. 2D. In this embodiment, at the moment when the bonded interface is solidified and fixed, the temperature of the first substrate A with a larger thermal expansion coefficient is lower than the temperature of the substrate B with a smaller thermal expansion coefficient. For this reason, the thermal shrinkage that occurs until the temperature of each of the substrates A and B is lowered back to the room temperature becomes smaller than in the conventional case where both the first and second substrates are heated up to the same temperature. In addition, the thermal stress of this embodiment is smaller than that in a comparative example where the temperatures of the two substrates A and B are kept at the same temperature. The above-described eutectic bonding is performed repeatedly five times. Consequently, all of the five sets of substrates are bonded together with the entire bonded surfaces, and neither slip lines nor cracks are observed.

Neither slips nor cracks are observed in any of all the substrates bonded together even if the sapphire substrates 25 is removed by a laser lift-off method as in the process described in FIG. 2E. Thus, the semiconductor device 1 with the structure shown in FIG. 1 can be obtained by providing the upper electrode 10 and the lower electrode 60 respectively on the first principal surface of the semiconductor laminate body 20 of the bonded substrate and the Si substrate 50, and by cutting out chips by performing dicing.

### First Comparative Example

FIG. 4B is a graph of a first comparative example where the time-temperature conditions for the upper heater plate 120 with the first substrate A mounted thereon are the same as those for the lower heater plate 130 with the second substrate B mounted thereon. In the first comparative example, to bond the first substrate A and the second substrate B together, both the temperature of the upper heater plate 120 and that of the lower heater plate 130 are raised from the room temperature T0 up to 300° C. in 20 minutes, then the temperatures are kept at 300° C. for a keeping time t1 of 60 minutes, and then the temperatures are lowered from 300° C. down to the room temperature T0 in 40 minutes.

Once the temperature of the bonding layer 40 becomes higher than the eutectic point, that is, the eutectic temperature (280° C.) of the AuSn material, the AuSn material contained in the second bonding layer 42 is turned into the eutectic state and is melted. Then, the Au and the Sn thus melted are diffused in a space between the first bonding layer 41 located above the second bonding layer 42 and the third bonding layer 43 located beneath the second bonding layer 42, and thereby the first bonding layer 41 and the third bonding layer 43 are turned into a single, unified body. The temperature of the bonding layer 40 is kept at the raised temperature for a keeping time t1 of 60 minutes, and then is lowered down. As a consequence, the melted AuSn material in the second bonding layer 42 becomes solidified, and thereby the two substrates A and B are bonded together in the bonding layer 40 as shown in FIG. 2D.

Five sets of substrates are bonded under the conditions of the first comparative example, and the vicinity of the bonded interface of each of the five bonded-substrate sets is inspected by using an ultrasonic flaw detector (SAT:Scanning Acoustic Tomograph). As a result, in every bonded-substrate set, slips are observed in the semiconductor laminate body 20 of the first substrate A.

In addition, if the sapphire substrate 12 is removed by the laser lift-off method in the process of removing the sapphire substrate 25 shown in FIG. 2E, cracks are formed in the support substrate 50 of the second substrate B in three of the five bonded-substrate sets.

As has been described thus far, the first substrate A and the second substrate B in the first comparative example are more likely to have slip lines and cracks as different from those in the first embodiment described above. This is because the eutectic bonding under different conditions is performed on the first substrate A and the second substrate B, which have different thermal expansion coefficients from each other. To be specific, in the eutectic bonding, once the temperature of the bonded-substrate set is started to be lowered, a thermal stress starts to be generated when the bonded surfaces of the two bonded substrates A and B are fixed to each other by the solidified eutectic system. Hence, the first substrate A including the sapphire substrate 25, which has a larger thermal expansion coefficient and shrinks by a larger amount, is pulled by the second substrate B including the Si substrate 50, which has a smaller thermal expansion coefficient and shrinks by a smaller amount, whereby a tensile stress is generated in the first substrate A. In contrast, a compressive stress is generated in the second substrate B including the Si substrate 50 because the second substrate B shrinks more than the first substrate A including the sapphire substrate 25. Accordingly, the thermal stress thus generated causes slips in the semiconductor laminate body 20 and cracks in the substrates.

As described earlier, in this first embodiment, when the first substrate A and the second substrate B are compared with each other, the peak temperature of the first substrate A with a larger thermal expansion coefficient is set at a lower temperature while the peak temperature of the second substrate B with a smaller thermal expansion coefficient is set at a higher temperature. For this reason, the tensile stress generated in the first substrate A and pulling the first substrate A towards the second substrate B can be reduced, and the slip lines and the cracks that would otherwise be generated by the thermal stress can be avoided.

Furthermore, as shown in this embodiment, it makes possible to make higher temperature of the interface of the second bonding layer 42 and the third bonding layer 43 compared with the interface of the second bonding layer 42 and the first bonding layer 41 during heat bonding treatment by forming the second bonding layer 42 in the first substrate A. Thereby, the diffusion reaction of the bonding interface of the second substrate B is promoted, and it becomes possible to obtain firmer bonding.

### Modified Example

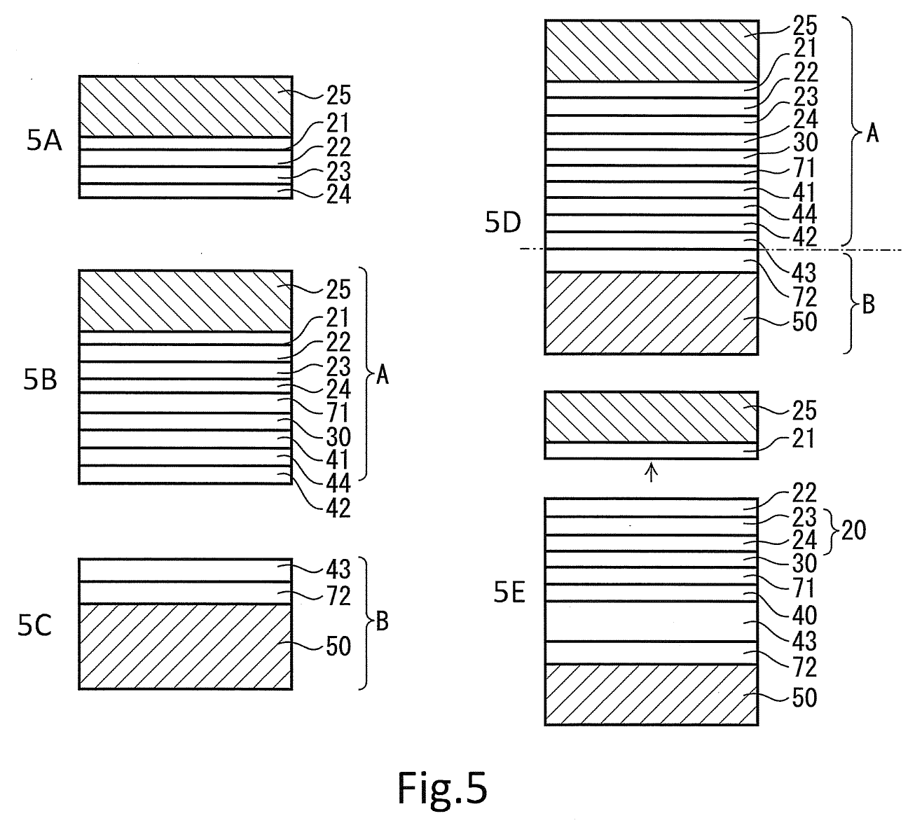

FIGS. 5A to 5E show schematic sectional views illustrating processes of manufacturing a semiconductor device 1 according to a first modified example of this embodiment. As FIGS. 5A to 5C show, when the semiconductor device 1 of this modified example is manufactured, an insert layer 44 is formed between the first bonding layer 41 and the second bonding layer 43 during the process of fabricating the first substrate A. In addition, the first substrate A further includes a first barrier layer 71 between the reflective layer 30 and the first bonding layer 41, while the second substrate B further includes a second barrier layer 72 between the third bonding layer 43 and the Si substrate 50.

The insert layer 44 may be, for example, a single Ti layer with a thickness of 20 nm. Each of the first barrier layer 71 and the second barrier layer 72 may have a triple-layer structure including a Ti layer with a 100-nm thickness, a Pt layer with a 200-nm thickness, and a Ti layer with a 100-nm thickness arranged in this order from the substrate side.

As FIG. 5D shows, the first substrate A and the second substrate B which include the above-described layers are bonded together along with a heat treatment.

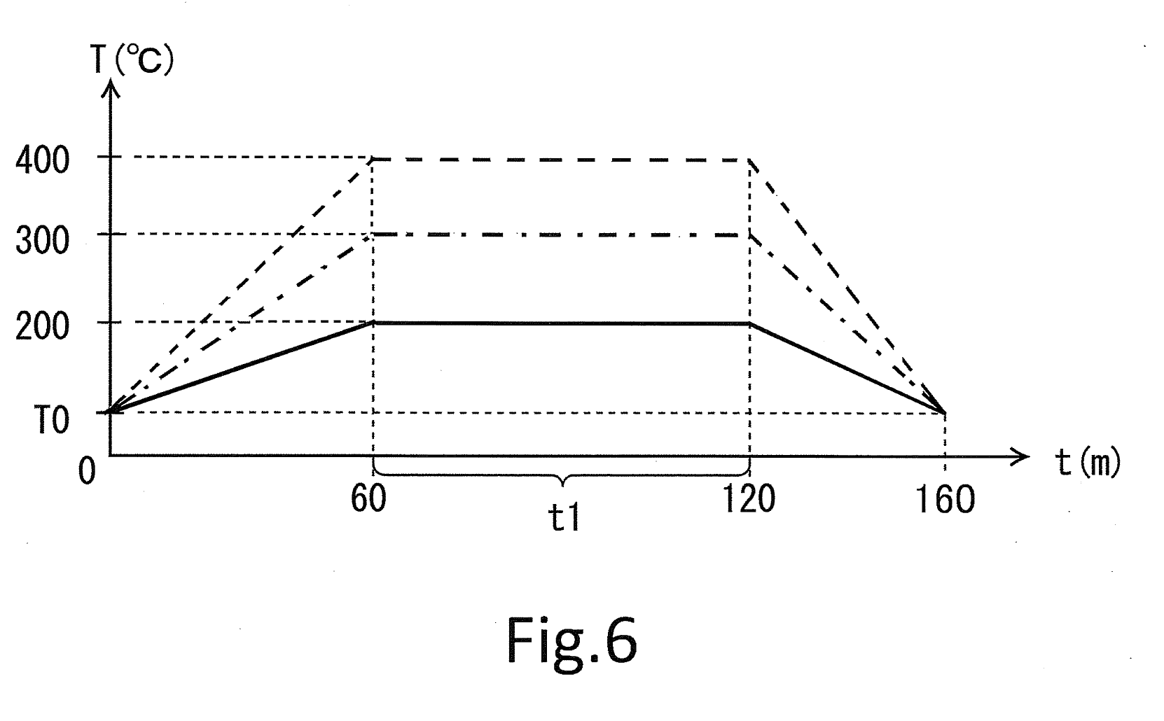

FIG. 6 is a graph illustrating the conditions of the time and the temperature related to the bonding and the pressure-bonding method according to the first modified example of this embodiment. The horizontal axis of the graph represents the time t (min), and the vertical axis represents the temperature T (° C.). Under the heat-bonding treatment conditions shown in FIG. 6, the temperature of the bonded-substrate set is raised at a slower pace than in the case of the bonding method described in the first embodiment, where no insert layer 44 is provided. To be specific, the raising of the temperature in this modified example takes 40 minutes longer than the time that it takes in the case of the first embodiment. The keeping time t1 in this modified example is set at 60 minutes as in the case of the above-described first embodiment.

Under the above-described time-temperature conditions, no bonded portions are observed in any of the substrates including the insert layer 44. In contrast, some unbonded portions are observed in all the substrates without the insert layer 44.

Such unbonded portions are left for the following reason. While the temperature of the substrate-set is being raised, the second bonding layer 42 is firstly melted. Then, interdiffusion of the second bonding layer 42 with both the first bonding layer 41 and the third bonding layer 43 takes place to transform these bonding layers 41 to 43 into a single, unified body, and thereby the first substrate A and the second substrate B are bonded together. Although the interdiffusion between the second bonding layer 42 and the third bonding layer 43 is essential to the bonding, this interdiffusion is preceded by the interdiffusion between the first bonding layer 41 and the second bonding layer 42 for the following reason. The first bonding layer 41 and the second bonding layer 42 are formed continuously by a deposition method or the like. Accordingly, there is no gap between these layers 41 and 42, and there are fewer impurities between these layers 41 and 42. In contrast, the third bonding layer 43 is formed on a substrate that is different from the one with the layers 41 and 42. The third bonding layer 43 is exposed to the outside air, and then is adhered to the second bonding layer 42, which is also exposed to the outside air, by the pressure applied in the bonding apparatus. Hence, there are microscopic gaps left, and some moisture and impurities adsorbed between the bonding layers 42 and 43. If there is a large time gap between the start of the diffusion of the first bonding layer 41 and the start of the diffusion with the second bonding layer 42, the low-melting-point content of the second bonding layer 42 is consumed by the diffusion and the reaction with the first bonding layer 41, leaving little such low-melting-point content that would react with the third bonding layer 43 and thereby allowing voids to be formed. The time gap between the reaction-start times becomes larger if the bonding surfaces are not smooth, if there are a lot of adsorbed impurities, and if the temperature is raised slowly. With a longer time gap, more unbonded portions are likely to be left.

If, as in the case of this modified example, the insert layer 44 is provided between the first bonding layer 41 and the second bonding layer 42, the diffusion and the reaction between the first bonding layer 41 and the second bonding layer 42 can be slowed down. Hence, the diffusion and the reaction between the second bonding layer 42 and the third bonding layer, the diffusion and the reaction which are necessary for the bonding, are not inhibited. Consequently, there are few, if any, unbonded portions left in the bonding layer 40.

### Second Embodiment

The second embodiment relates to a method of bonding together two substrates with different thermal expansion coefficients by using a direct bonding method. A specific description will be given below of a method in which a substrate containing a compound semiconductor obtained by epitaxially growing an InGaAlP on a GaAs substrate and a substrate obtained by epitaxially growing a GaP film on a GaP substrate are prepared and the two substrates are bonded together by using the direct bonding method. However, substrates usable for this embodiment are not limited to the substrates as described above. For example, the embodiment is also applicable to a method of bonding a silicon substrate to a substrate obtained by epitaxially growing a GaN epitaxial layer on a sapphire substrate.

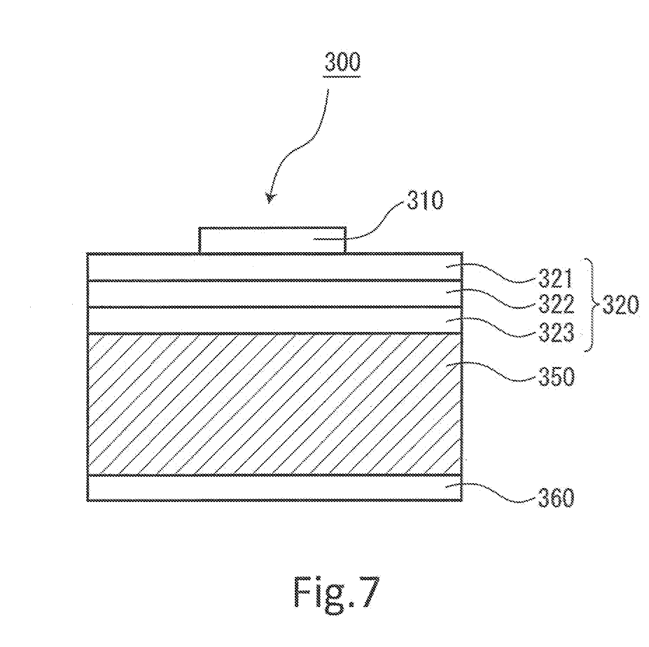

FIG. 7 is a schematic sectional view illustrating a semiconductor device 300 for a method of manufacturing a semiconductor according to the second embodiment. As FIG. 7 shows, the semiconductor device 300 is, for example, an InGaAlP-based LED. The semiconductor device 300 includes, from above, an upper electrode 310, a semiconductor laminate body 320, a substrate 350, and a lower electrode 360.

The semiconductor laminate body 320 has a first principal surface and a second principal surface. The upper electrode 310 is provided on the first-principal-surface side. The support substrate 350 and the lower electrode 360 are provided on the second-principal-surface side. The semiconductor laminate body 320 is formed by epitaxially growing an InGaAlP on an unillustrated N-type GaAs substrate 324 used as a substrate for growth. To be specific, the semiconductor laminate body 320 includes an n-type clad layer 321 located on the first-principal-surface side, a p-type clad layer 323 located on the second-principal-surface side, and an active layer 322 interposed therebetween, all of which are laminated with one another. Note that, the semiconductor laminate body 320 may include a contact layer (not illustrated) to make contact with the upper electrode 310, and may include a transparent conductive film (not illustrated) to improve the luminance. The active layer 322 may have a DH (double hetero) MQW (multiple-quantum well) structure, for example. The active layer 322 is sandwiched by the n-type clad layer 321 and the p-type clad layer 323 from both sides, and thereby traps the carriers in the vertical direction.

The GaP transparent substrate 350 is provided on the second-principal-surface side of the semiconductor laminate body 320. The transparent substrate 350 is made, for example, of GaP, and has a size of 3-inch diameter and a 300-μm thickness. The support substrate 350 may be a p-type substrate containing impurities of Zn at a concentration of 1×10¹⁸/cm³, for example.

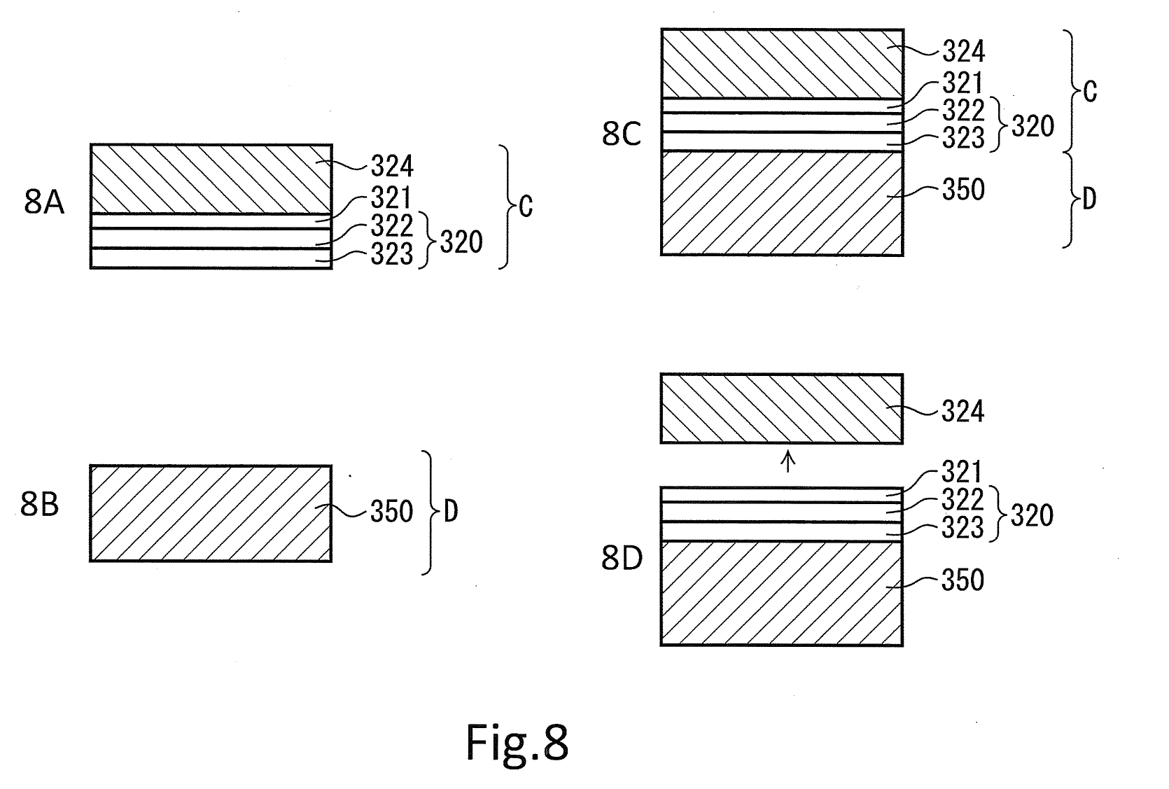

FIGS. 8A to 8D show schematic sectional views illustrating processes of manufacturing the semiconductor device 300 according to this embodiment.

As FIG. 8A shows, the semiconductor laminate body 320 is firstly formed by epitaxially growing an InGaAlP on an n-type GaAs substrate 324 (thermal expansion coefficient=5.2×10⁻⁶/K). The semiconductor laminate body 320 includes the n-type clad layer 321, the active layer 322, and the p-type clad layer 323, which are provided in this order from the side of the GaAs substrate 324. The semiconductor laminate body 320 is formed, for example, by using an epitaxial-growth apparatus such as an MOCVD (metal organic chemical vapor deposition) apparatus.

The n-type GaAs substrate 324 has a size of a 3-inch diameter and a 300-μm thickness, and contains impurities of Si doped at a concentration of approximately 1×10¹⁸/cm³. A buffer layer (not illustrated) may be provided between the GaAs substrate 324 and the semiconductor laminate body 320.

In this embodiment, the n-type clad layer 321 has a 1-μm thickness, the active layer 322 has a 0.6-μm thickness, and the p-type clad layer 323 has a 0.6-μm thickness. Hereinafter, a term “third substrate C” is used for the sake of descriptive convenience to mention a substrate obtained by forming the semiconductor laminate body 320 on the GaAs substrate 324.

On the other hand, as FIG. 8B shows, the GaP substrate (thermal expansion coefficient=4.7×10⁻⁶/K) 350 is used as a support substrate.

Note that the GaP substrate 350 serving as a transparent substrate may be obtained by epitaxially growing a GaP film on the GaP substrate 350. To be specific, the GaP substrate 350, which has a size of a 3-inch diameter and a 300-μm thickness, is formed by growing a GaP film by the MOCDV method on a p-type substrate containing impurities of Zn with a concentration of 1×10¹⁸/cm³ so that the concentration of the GaP impurities can be 3×10¹⁸/cm³. Note that, the GaP substrate 350 may contain In, Al, or the like. Hereinafter, a term “fourth substrate D” is used for the sake of descriptive convenience to mention the GaP substrate 350.

In the third substrate C of this embodiment, the total thickness of InGaAlP is 2.3 μm, which is not thicker than 1% of the thickness of the GaAs substrate 324 serving as the growth substrate. Hence, the InGaP epitaxial substrate has a thermal expansion coefficient that is substantially equal to the thermal expansion coefficient of the GaAs substrate 324. To be specific, the InGaP epitaxial substrate has a thermal expansion coefficient of 5.2×10⁻⁶/K.

Even if the GaP epitaxial layer of the GaP substrate 21 included in the fourth substrate D contains such contents as In, Al, and others, the thickness of the GaP epitaxial layer is small in comparison to the thickness of the GAP substrate 21. Hence, the epitaxial substrate has substantially similar physical properties to those of the GaP substrate 21.

The third substrate C and the fourth substrate ID, which have different thermal expansion coefficients from each other are washed by an ordinary, compound-semiconductor washing method, such as a washing method using an organic solvent, a surfactant, or the like. Then, the surface oxide films of the substrates C and D are removed by using dilute hydrofluoric acid or ammonium fluoride. After that, the substrates C and D are washed with water and are spin-dried. Thus, the substrates C and D are ready for the bonding. In the series of treatments described above, OH-groups are formed on the surfaces of the substrates C and D.

Then, as FIG. 8C shows, the two substrates C and D are adhered to each other at room temperature in an atmosphere of clean air. The OH-groups formed on the surfaces of the two substrates C and D attract each other with the force of the hydrogen bonding, so that the two substrates C and D are adhered together firmly enough only by adhering the two substrates C and ID to each other at room temperature. Consequently, the two substrates C and ID thus adhered firmly can be considered as a single, unified substrate, which is then subjected to a heat treatment to make the bonding even stronger.

Finally, as FIG. 8D shows, the GaAs substrate 324 is removed from the bonded-substrate unit by a selective etching process using a mixed solution of hydrogen peroxide solution and ammonia.

After that, the upper electrode 310 and the lower electrode 360 are formed, and then the wafer is diced into chips in a dicing process. Thus obtained is the semiconductor device 300 with the shape shown in FIG. 7.

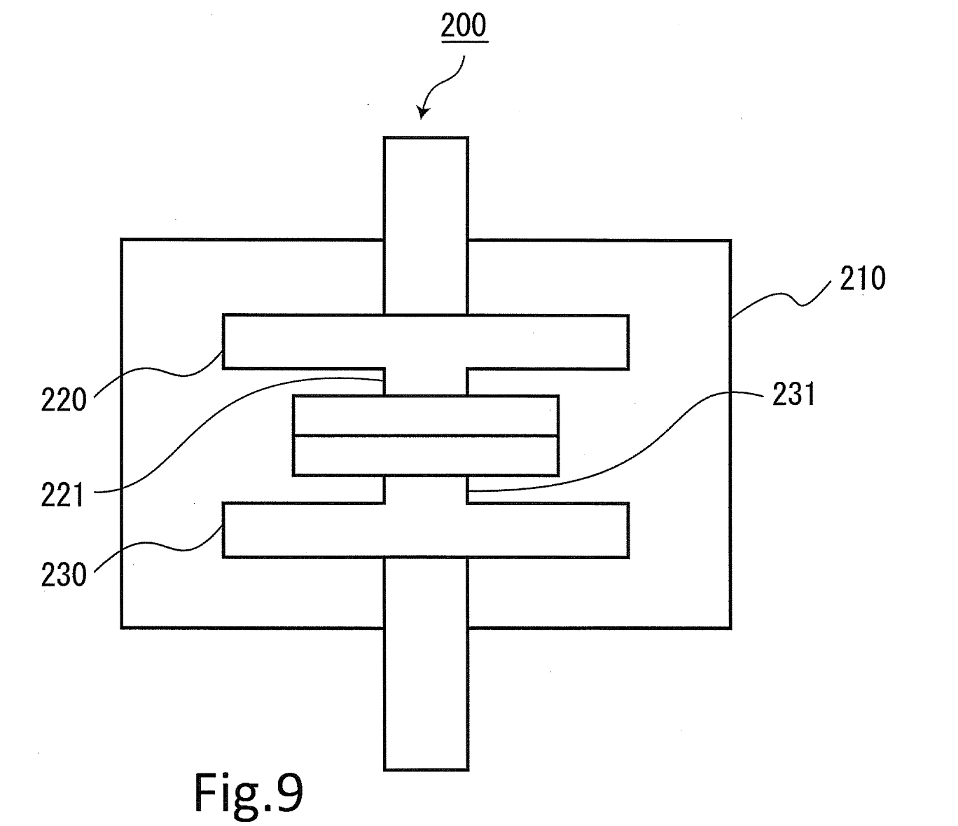

FIG. 9 is a schematic sectional view illustrating a process of bonding the third substrate C and the fourth substrate D by using a heater apparatus 200. The heater apparatus 200 includes a vacuum chamber 210, an upper heater plate 220, and a lower heater plate 230. The vacuum chamber 210 can set its atmosphere to be a vacuum atmosphere, a reduced-pressure atmosphere, or an inert-gas atmosphere in the same manner as the heater apparatus 100 shown in FIG. 3. In addition, the heater apparatus 200 has a function to control individually the temperature of the upper heater plate 220 and the temperature of the lower heater plate 230. Moreover, the heater apparatus 200 has a mechanism (not illustrated) to apply a load, up to approximately 10 tons, to the substrates interposed between the upper heater plate 220 and the lower heater plate 230.

As FIG. 9 shows, the heater apparatus 200 of this embodiment may have both a projection 221 formed in a central portion of the upper heater plate 220 and a projection 231 formed in a central portion of the lower heater plate 230. Alternatively, each of the heater plates 220 and 230 has a convex surface with the central portion raised higher than the peripheral portions. The raised central portion eliminates the necessity of forcibly correcting the warpage, which is caused by the thermal stress and the thermal strain, and which would otherwise be corrected by applying a large load onto the entire surfaces of the two substrates C and D during the heat treatment. In addition, the raised central portion can reduce the residual strain left when the bonded-substrate unit is cooled down to the room temperature and the thermal strain is released.

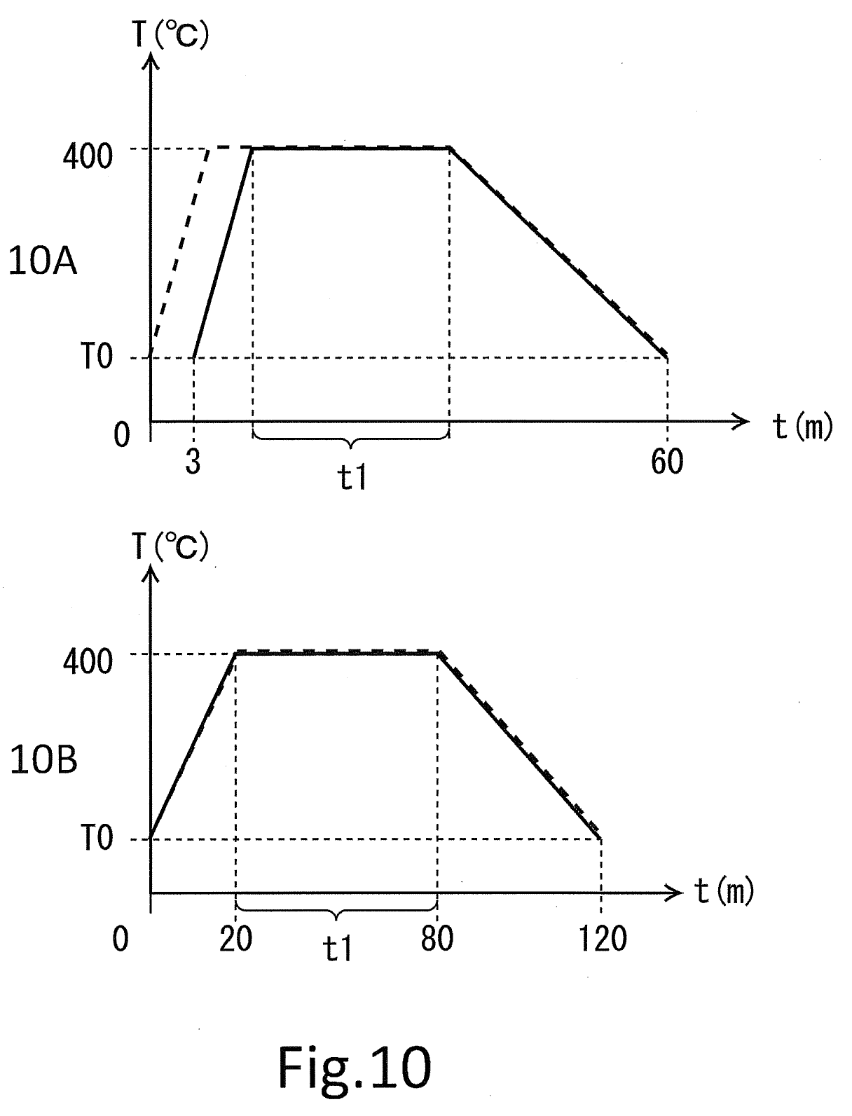

FIGS. 10A and 10B show graphs illustrating conditions of time and temperature related to the bonding method of this embodiment. The horizontal axis of each graph represents the time t (min), and the vertical axis represents the temperature T (° C.). Solid line A represents the time-temperature conditions for the upper heater plate 220, and dashed line B represents the time-temperature conditions for the lower heater plate 230.

In this embodiment, the third substrate C includes the GaAs substrate 324 with a thermal expansion coefficient of 5.2×10⁻⁶/K while the fourth substrate D includes the GaP substrate 350 with a thermal expansion coefficient of 4.7×10⁻⁶/K. The upper heater plate 220 with the third substrate C mounted thereon and the lower heater plate 230 with the fourth substrate D mounted thereon are controlled by using different time-temperature conditions.

In this embodiment, as FIG. 10A shows, the temperature of the lower heater plate 220 is raised from the room temperature T0 at a rate of 20 degrees per minute. The temperature of the upper heater plate 230 is raised from the room temperature T0 at a rate of 20 degrees per minute, but this temperature raising is started 3 minutes later than the start of the temperature raising for the lower heater plate 220. The temperatures of the two heater plate 220 and 230 are raised up to 400° C., and then are kept constant. The temperatures are kept at 400° C. for 60 minutes from the time when the temperature of the upper heater plate 230, whose temperature starts rising later, reaches 400° C. (keeping time t1=60). Then, the temperatures of the two heater plates 220 and 230 are lowered from 400° C. down to the room temperature T0. The lowering of the temperature of the lower heater plate 220 and that of the upper heater plate 230 start simultaneously. Both of the temperatures of the two heater plates 220 and 230 are lowered at a rate of 5 degrees per minute. Note that the two substrates C and D of this embodiment are adhered to each other at room temperature to be transformed into a single, unified body, and the two substrates C and D are bonded together more firmly by heating the single, unified body thus obtained with the heater apparatus 200 to increase the adhesion strength. Accordingly, though the two substrates A and B are pressure-bonded together by applying a load in the first embodiment, such pressure-bonding is not necessary in the second embodiment.

Five sets of substrates are bonded by the direct bonding described above. When the substrates after the bonding are inspected, no cracks, no separations and no slip lines have occurred in any of the five sets.

### Second Comparative Example

FIG. 10B is a graph of a second comparative example where the time-temperature conditions for the upper heater plate 220 with the third substrate C mounted thereon are the same as those for the lower heater plate 230 with the fourth substrate D mounted thereon. Both the temperature of the upper heater plate 220 and that of the lower heater plate 230 are raised from the room temperature T0 up to 400° C. at a rate of 20° C. per minute, then the temperatures are kept at 400° C. for a keeping time t1 of 60 minutes, and then the temperatures are lowered from 400° C. down to the room temperature T0 in 80 minutes at a rate of 5° C. per minute.

Five sets of substrates are bonded under the conditions of the second comparative example, and the vicinity of the bonded interface of each of the five bonded-substrate sets is inspected by using anoptical microscope. As a result, in two of the five bonded-substrate sets, slips are observed in the semiconductor laminate body of the third substrate C. As has been described thus far, in this embodiment, the raising of the temperature of the upper heater plate 220 where the third substrate C with a larger thermal expansion coefficient is mounted starts 3 minutes later than the start of the temperature-raising for the lower heater plate 230. Consequently, while the temperatures of the two heater plates 220 and 230 are being raised, the temperature of the upper heater plate 220 is kept 60° C. lower than the temperature of the lower heater plate 230 where the fourth substrate D with a smaller thermal expansion coefficient is mounted. Assuming a linear temperature-changing pattern within each of the substrates sandwiched between the two heater plates 220 and 230, the temperature of the central portion of the third substrate C in section is 30° C. lower than the temperature of the central portion of the fourth substrate D in section. Accordingly, the third substrate C expands by heat less than the amount by which the third substrate C would otherwise expand. Consequently, both the thermal stress and the thermal stress between the two substrates C and D are reduced, so that the separation of the two substrates becomes less likely to happen.

There is no difference between this embodiment and the second comparative example in the thermal stress and the thermal strain that act in a state where both of the temperatures of the two substrates are kept at 400° C. Nevertheless, the temperature of the first substrate C and the temperature of the second substrate D are made to be different from each other during the temperature raising process in which the adhesion strength between the two substrates C and D is not strong enough to prevent the two substrates C and D from being separated from each other. The temperature difference between the two substrates C and D contributes to preventing the separation.

In addition, not only in the case of the direct bonding, but also in the cases of bonding methods where the adhesion strength is increased by the temperature-raising, the separation of the substrates can be prevented by causing the temperature of the substrate with a larger thermal expansion coefficient to be lower than the temperature of the substrate with a smaller thermal expansion coefficient during the temperature raising process.

### First Modified Example

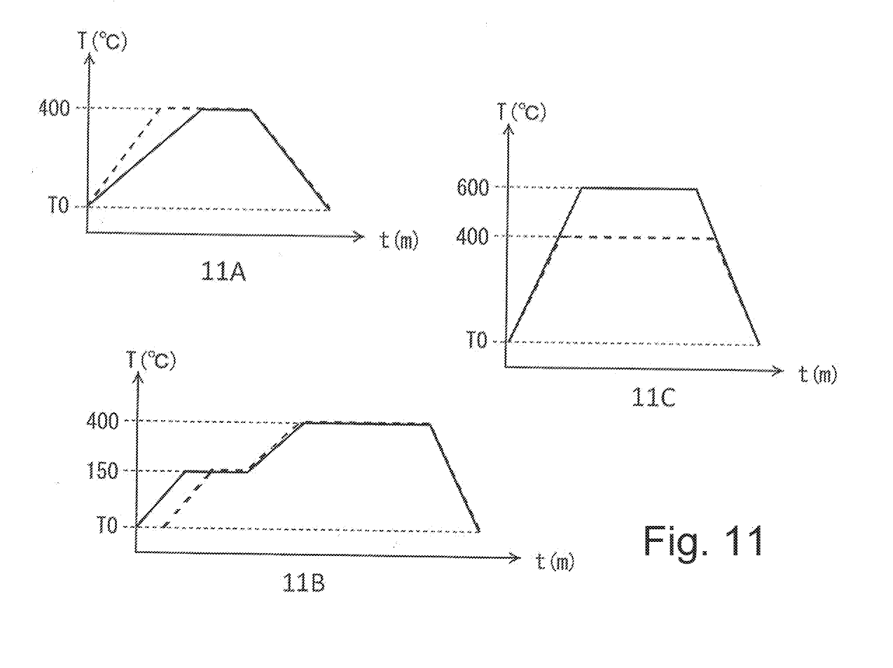

FIG. 11A is a graph illustrating the time-temperature conditions for the bonding method according to a first modified example of the second embodiment.

In this modified example, the temperature of the upper heater plate 220 is raised at a different rate from the corresponding rate for the lower heater plate 230 so that a larger difference in temperature than in the case of the first embodiment can be obtained during the temperature raising process. For example, the temperature of the upper heater plate 220 where the third substrate C with a larger thermal expansion coefficient is mounted is raised at 16 degrees per minute (see the solid line), whereas the temperature of the upper lower plate 230 where the fourth substrate D with a smaller thermal expansion coefficient is mounted is raised at 20 degrees per minute (see the dashed line). The temperatures of the two heater plates 220 and 230 are kept at 400° C. Consequently, a maximum temperature difference of 80° C. can be obtained.

Five sets of substrates are bonded in the first modified example. No separations and no slips have occurred in any of the five sets.

### Second Modified Example

FIG. 11B is a graph illustrating the time-temperature conditions for the bonding method according to a second modified example of the second embodiment. In the second modified example, the keeping time for the temperature of each heater plate is set twice so that the two substrates can have a constant adhesion strength. In the second modified example, the temperature of the lower heater plate 230 is raised at a rate of 20 degrees per minute up to 150° C., and then is temporarily kept at 150° C. for a keeping time t1 of 30 minutes. On the other hand, the raising of the temperature of the upper heater plate 220 is started 3 minutes later than the raising of the temperature of the lower heater plate 230, and the temperature of the upper heater plate 220 is temporarily kept at 150° C. After the keeping time t1 is elapsed, the raising of the temperature of the lower heater plate 230 is resumed until the temperature reaches 400° C. The raising of the temperature of the upper heater plate 220 is performed at the same timing and at the same rate as that for the lower heater plate 230. Once the temperatures of the two heater plates 220 and 230 reach 400° C., the temperatures of the two heater plates 220 and 230 are kept at 400° C. for a keeping time t2 of 60 minutes. After the keeping time t2 is elapsed, the temperatures of the upper heater plate 220 and the lower heater plate 230 are lowered at a rate of 5 degrees per minute. This temperature-changing pattern causes a dehydration condensation reaction to take place, so that the bonding of the two substrates can be made stronger.

Five sets of substrates are bonded in the second modified example. No separations and no slips have occurred in any of the five sets.

### Third Modified Example

FIG. 11C is a graph illustrating the time-temperature conditions for the bonding method according to a third modified example of the second embodiment. In the third modified example, the temperature-raising rate for the upper heater plate 220 is set the same as that for the lower heater plate 230. However, the two heater plates 220 and 230 are set to differ in the peak temperature and the duration of the peak temperature.

In the third modified example, the temperature of the lower heater plate 230 where the fourth substrate D is mounted is raised from the room temperature T0 up to 600° C. at a rate of 6 degrees per minute. The temperature of the lower heater plate 230 is kept at 600° C. for 60 minutes, and then is lowered from 600° C. down to the room temperature T0 at a rate of 6 degrees per minute.

The temperature of the upper heater plate 220 where the third substrate C is mounted starts to be raised at the same timing and at the same rate (6 degrees/min) as that for the lower heater plate 230. Once the temperature of the upper heater plate 220 reaches 400° C., the temperature is kept at 400° C. until the temperature of the lower heater plate 230 is lowered back to 400° C. When the declining temperature of the lower heater plate 230 reaches 400° C., the temperature of the upper heater plate 220 starts to be lowered from 400° C. down to the room temperature T0. The temperature of the upper heater plate 220 is lowered down to the room temperature T0 at the same rate as that for the lower heater plate 230, that is, at 6° C./min.

Five sets of substrates are bonded in the third modified example. No separations and no slips have occurred in any of the five sets.

In the third modified example, the peak temperature for the lower heater plate 230 is higher than the corresponding peak temperature in the second comparative example shown in FIG. 10B. The thermal stress, however, becomes smaller with the temperature difference between the two substrates C and D during the temperature raising process. Hence, slips are less likely to occur. Not only the temperature difference during the temperature raising process but also the difference in peak temperature between the third substrate C and the fourth substrate D contributes to reducing the thermal stress. Accordingly, the occurrence of slips can be prevented more effectively.

Fifty LED chips manufactured by the manufacturing method of the third modified example are made to emit light by continuously energizing for a week, and then subjected to a reliability test to compare the luminances before and after the energization. If, in this reliability test, an LED shows the decline in luminance by 5% or more, that LED is regarded as defective. The percent defective for the LEDs manufactured by the method of the third modified example is 0%, but the percent defective for the LEDs manufactured in the method of the above-described second comparative example is 6% ( 3/50).

### Third Embodiment

The third embodiment relates to a method of bonding together two substrates with different thermal expansion coefficients by surface activated bonding. A specific description will be given below of a method in which a Si substrate and a substrate containing a compound semiconductor obtained by epitaxially growing an InGaAlP on a GaAs substrate are prepared and the two substrates are bonded together using Au by surface activated bonding. However, substrates usable for this embodiment are not limited to the substrates as described above. For example, the embodiment is also applicable to a method of bonding a silicon substrate to a substrate obtained by epitaxially growing a GaN epitaxial layer on a sapphire substrate.

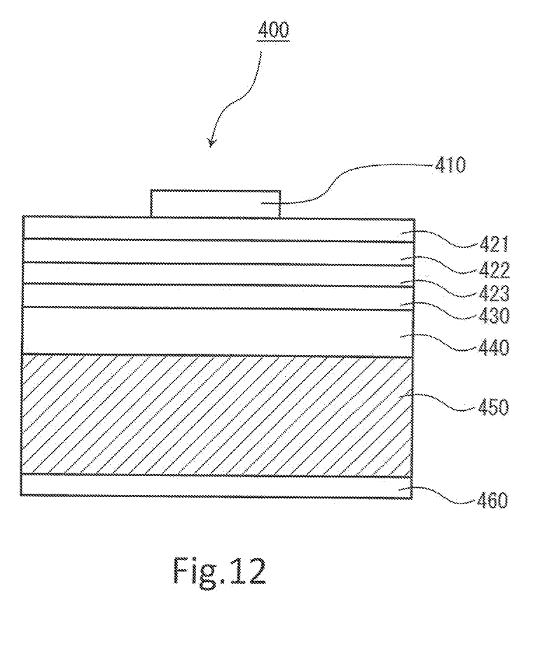

FIG. 12 is a schematic sectional view illustrating a semiconductor device 400 for a method of manufacturing a semiconductor according to the third embodiment. As FIG. 12 shows, the semiconductor device 400 is an InGaAlP-based LED in the same manner as the second embodiment. The semiconductor device 400 of this embodiment, however, differs from the semiconductor device 300 described in the second embodiment because the semiconductor device 400 of this embodiment further includes a bonding layer 440 that includes both a first bonding layer 441 and a second bonding layer 442. In addition, the semiconductor device 400 of this embodiment may also include a reflective layer 430.

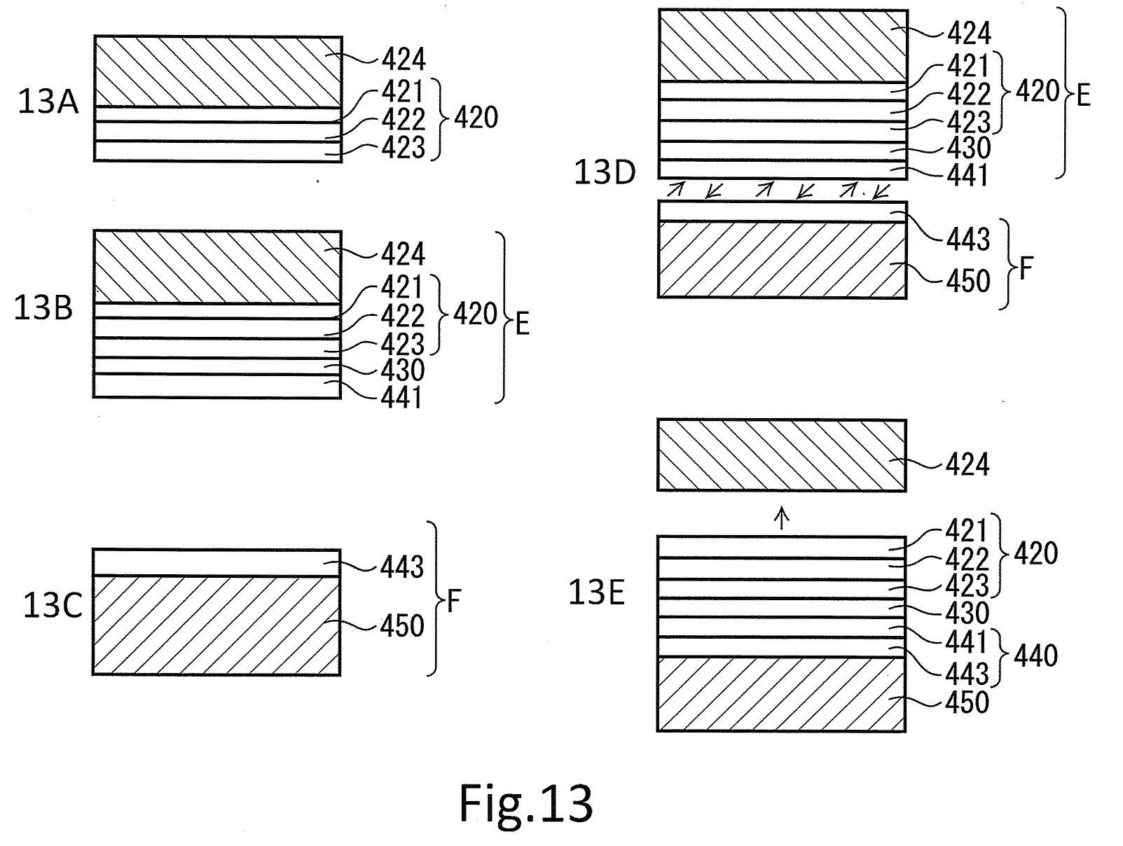

FIGS. 13A to 13E show schematic sectional views illustrating processes of manufacturing the semiconductor device 400 according to this embodiment.

As FIG. 13A shows, the semiconductor laminate body 420 is firstly formed by epitaxially growing an InGaAlP on an n-type GaAs substrate (thermal expansion coefficient=5.2×10⁻⁶/K) in this embodiment. The semiconductor laminate body 420 includes the n-type clad layer 421, the active layer 422, and the p-type clad layer 423, which are provided in this order from the side of the GaAs substrate. The semiconductor laminate body 420 is formed, for example, by using an epitaxial-growth apparatus such as an MOCVD (metal organic chemical vapor deposition) apparatus.

Next, as FIG. 13B shows, a reflective layer 430 made mainly of Ag, Ag alloy, and Al is formed on the second principal surface of the semiconductor laminate body 420. The reflective layer 430 preferably has a thickness ranging from 50 to 1 μm to maintain high reflectivity. The reflective layer 430 of this embodiment is assumed to have a thickness of 1 μm for the sake of descriptive convenience. If the reflective layer 430 is made mainly of Ag, the reflective layer 430 can be patterned by either an etching method using a solution containing phosphoric acid or a dry etching method.

In addition, the reflective layer 430 may be formed to cover the entire surface of the chip as in the case shown in FIG. 13B, or may be formed only in portions that need reflection. In the latter case, the reflective layer 430 is firstly formed on the entire second principal surface of the semiconductor laminate body 420, and then the reflective layer 430 is patterned using a photoresist to leave the reflective layer 430 partially on the second principal surface of the semiconductor laminate body 420. Furthermore, to keep a larger adhesion strength with the semiconductor laminate body 420 in the dicing process, the second metal may be patterned (not illustrated). The second metal may be Au, or other metals such as Pd and Pt.

Then, the first bonding layer 441 is formed on the second-principal-surface side of the semiconductor laminate body 420. The first bonding layer 441 is made mainly of gold (Au), and has a thickness of 0.5 μm. The first bonding layer 441 can be formed by the sputtering method. Hereinafter, a term “fifth substrate E” is used for the sake of descriptive convenience to mention the substrate obtained by forming the reflective layer 430 and the first bonding layer 441 on the semiconductor laminate body 420.

On the other hand, as FIG. 13C shows, a second bonding layer 443 serving as a support substrate is formed on a Si substrate 450 (thermal expansion coefficient=4.2×10⁻⁶/K). The Si substrate 450 of this embodiment is a p-type low-resistance substrate. Hereinbelow, a term “sixth substrate F” is used to mention a substrate in a state where the second bonding layer 443 is formed on the Si substrate for the sake of descriptive convenience.

Then, as FIG. 13D shows, sputtering with Ar is performed in this embodiment for 2 minutes in the bonding interface where the fifth substrate E and the sixth substrate F are bonded together, and thereby the surfaces are activated. As the bonding interface is hit by the sputtered Ar, the contaminants attached to the surfaces, the naturally-formed oxide films on the surfaces, and the like are removed from the surfaces. In addition, the bondings that have been formed with the oxide films formed on and the objects attached to the wafer surfaces are cut off, leaving the wafer surfaces in the activated state, that is, a state where the wafer surfaces are more likely to form bonding with other materials.

Note that the surface activation may be done also by a method other than the sputtering with Ar. For example, the activation can be done by using FAB (fast atomic beam), plasma, or the like. In addition, for the purpose of the activation, the beams may be applied perpendicularly, i.e. not obliquely as shown in FIG. 13D. To this end, a mechanism to move the substrates in horizontal direction may be provided to move the substrates to the positions for the perpendicular activation and then to move the substrates horizontally to the positions for the bonding. Still alternatively, the activation may be done by using an apparatus or a chamber that is different from the apparatus for the bonding.

Then, once the activation is done, the heater plates are moved to adhere the two substrates E and F with different thermal expansion coefficients to each other by the surface activated bonding, and the heater plates apply heat to the substrates to increase the bonding strength. To be specific, a load of 300 kg is set to this end.

Finally, as FIG. 13E shows, the GaAs substrate 424 is removed from the bonded-substrate unit by a selective etching process using hydrogen peroxide solution and ammonia. Then, the upper electrode 410 and the lower electrode 460 are formed into the bonded-substrate unit. Thus obtained is the semiconductor device 400 shown in FIG. 12.

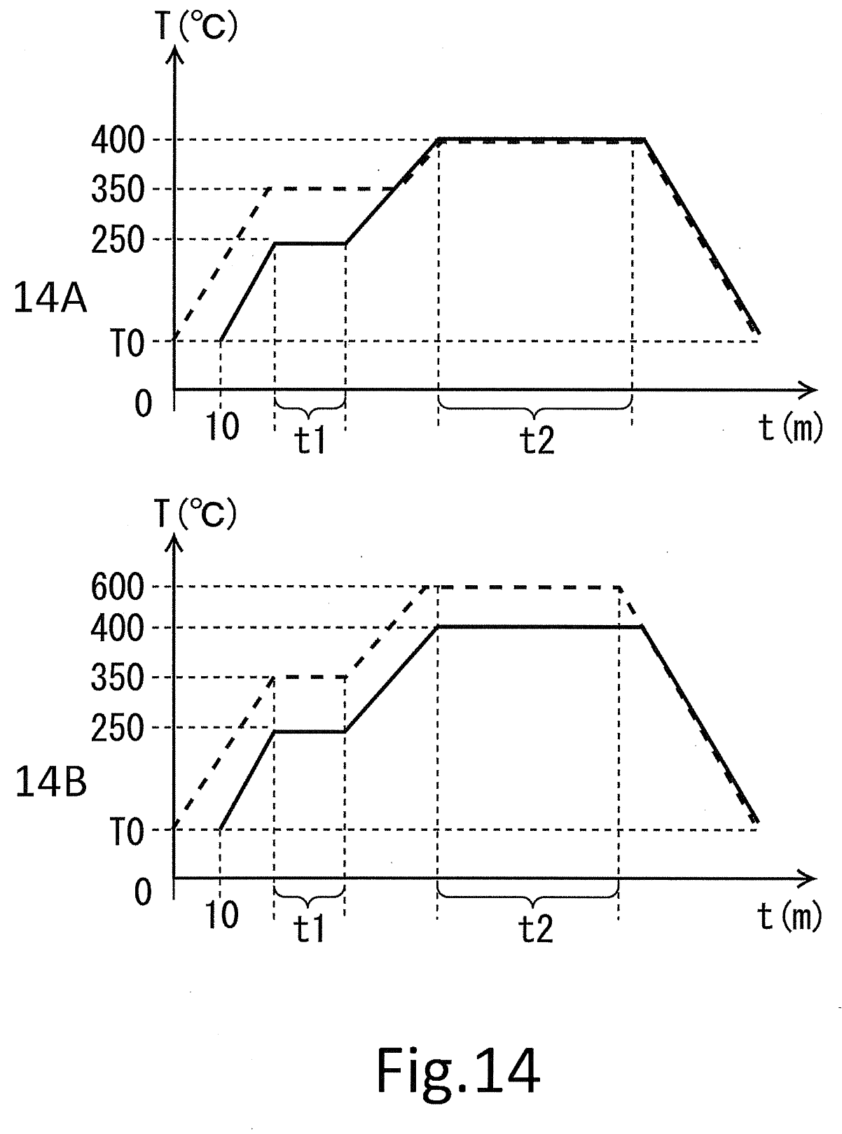

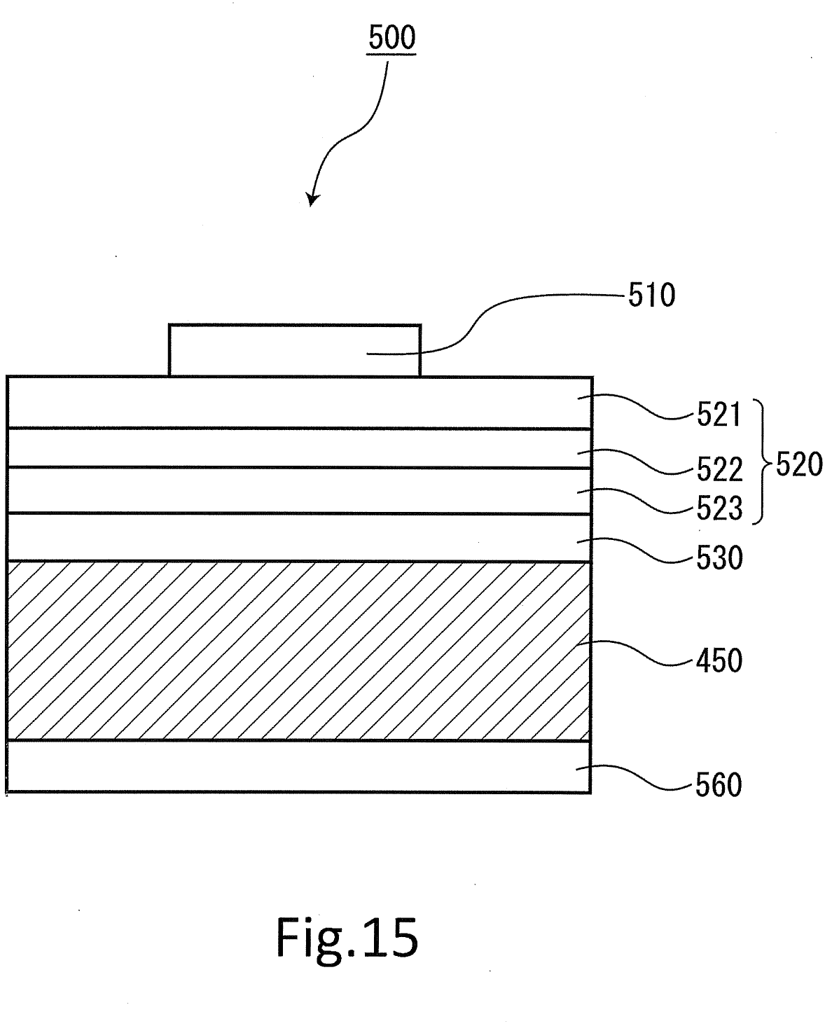

FIGS. 14A and 14B show graphs illustrating conditions of time and temperature related to the bonding method of this embodiment. The horizontal axis of each graph represents the time t (min), and the vertical axis represents the temperature T (° C.). The solid lines represent the time/temperature of the upper heater plate 220, the dashed lines represent the time/temperature of the lower heater plate 230.

In this embodiment, the fifth substrate E including the GaAs substrate (thermal expansion coefficient=5.2×10⁻⁶/K) is mounted on the upper heater plate 220, while the sixth substrate F including the Si substrate (thermal expansion coefficient=4.2×10⁻⁶/K) is mounted on the lower heater plate 230.

FIG. 14A is a graph illustrating the time-temperature conditions for the bonding method of this embodiment. The temperature-raising for the upper heater plate 220 is started at a timing different from the timing at which the temperature-raising for the lower heater plate 230 is started. The temperature of the upper heater plate 220 is kept at 250° C. and at 400° C. The temperature of the lower heater plate 230 is also kept at 350° C. and at 400° C. To be more specific, the temperature of the lower heater plate 230 is raised at a rate of 10 degrees per minute from the room temperature T0 up to 350° C., and is kept at 350° C. Then, 10 minutes after the start of the temperature-raising for the lower heater plate 230, the temperature of the upper heater plate 220 starts to be raised at a rate of 10 degrees per minute. Once the temperature of the upper heater plate 220 reaches 250° C., the temperature of the upper heater plate 220 is kept at 250° C. for a keeping time t1 of 10 minutes. Then, the temperature-raising for the upper heater plate 220 is resumed, and the temperature is raised again at a rate 10 degrees per minute. When the temperature of the upper heater plate 220 reaches 350° C., the temperature-raising for the lower heater plate 230 is resumed. Both the temperature of upper heater plate 220 and the temperature of the lower heater plate 230 are then raised at the same rate of 10 degrees per minute until reaching 400° C. simultaneously. Both the temperature of the upper heater plate 220 and the temperature of the lower heater plate 230 are kept at 400° C. for a keeping time t2 of 120 minutes, and are then lowered down at a rate of 10 degrees per minute.

By the surface activated bonding of this embodiment, a strong bonding can be obtained without any heat treatment as long as the bonding surfaces are perfectly flat, the impurities attached to the surfaces are removed completely by the activation, and the bonding atmosphere is an ultrahigh vacuum atmosphere that can prevent the re-adsorption to the bonding surfaces. The actual conditions, however, are far from the ideal, because the bonding surfaces have microscopic asperities and re-adsorption does take place. So it is preferable to perform a heat treatment to promote the solid-phase diffusion between the bonding layers and to increase the bonding strength.

Note that neither separation nor breakage of the substrates takes place in this embodiment.

### First Modified Example

FIG. 14B is a graph illustrating the time-temperature conditions for the bonding method according to a first modified example of the third embodiment. In this modified example, the temperature-raising for the upper heater plate 220 is started at a different timing from the timing at which the temperature-raising for the lower heater plate 230 is started. In addition, the temperature of the upper heater plate 220 is kept at 250° C. and at 400° C. The temperature of the lower heater plate 230 is kept 350° C. and at 600° C. To be more specific, the temperature of the lower heater plate 230 is raised at a rate of 10 degrees per minute from the room temperature T0 up to 350° C., and is kept at 350° C. Then, 10 minutes after the start of the temperature-raising for the lower heater plate 230, the temperature of the upper heater plate 220 starts to be raised at a rate of 10 degrees per minute. Once the temperature of the lower heater plate 230 reaches 350° C. and the temperature of the upper heater plate 220 reaches 250° C., the temperature of the upper heater plate 220 is kept at 250° C. and the temperature of the lower heater plate 230 is kept at 350° C. both for a keeping time t1 of 10 minutes. After that, the temperature-raising for both the upper heater plate 220 and the lower heater plate 230 are resumed simultaneously both at a rate of 10 degrees per minute. Then, once the temperature of the lower heater plate 230 reaches 600° C. and the temperature of the upper heater plate 220 reaches 400° C., the temperature of the upper heater plate 220 is kept at 400° C. and the temperature of the lower heater plate 230 is kept at 600° C. The temperature of the lower heater plate 230 is kept at 600° C. for a keeping time t2 of 60 minutes. Then, the temperature of the lower heater plate 230 is lowered at a rate of 10 degrees per minute. When the temperature of the lower heater plate 230 reaches 400° C., the temperature-lowering for the upper heater plate 220 is resumed at a rate of 10 degrees/min until the temperature of the upper heater plate 220 reaches the room temperature T0.

As has been described thus far, if the surface activated bonding is accompanied by a heat treatment, an effect to increase the bonding strength can be obtained. If the surface activated bonding is performed only at room temperature without any heat treatment, atoms in the atmosphere, though the atmosphere is a vacuum atmosphere, are re-adsorbed to the activated surfaces, so that the bonding strength is impaired. The heat treatment can diffuse the adsorbed atoms, or can promote the solid-phase diffusion of Au atoms on the surfaces of the two substrates, so that the two substrates can be bonded together into a single, unified body with a larger bonding strength.

Note that the bonding material used in this embodiment is gold (Au). It is, however, allowable that various metals other than Au, e.g. Cu, or surfaces of Si semiconductor crystal or of a compound semiconductor crystal, or surfaces of epitaxial layers can be used in the surface activated bonding.

### Fourth Embodiment

This embodiment relates to a liquid-phase diffusion metallic bonding method to bond two substrates of different kinds with different thermal expansion coefficients from each other. Hereinafter, a liquid-phase diffusion metallic bonding method is described where a Si substrate and a substrate containing a compound semiconductor formed by epitaxially growing InGaAlP on a GaAs substrate. These substrates are not the only possible substrates that can be used in this embodiment. For example, the embodiment is also applicable to a method of bonding a silicon substrate to a substrate obtained by epitaxially growing a GaN epitaxial layer on a sapphire substrate.

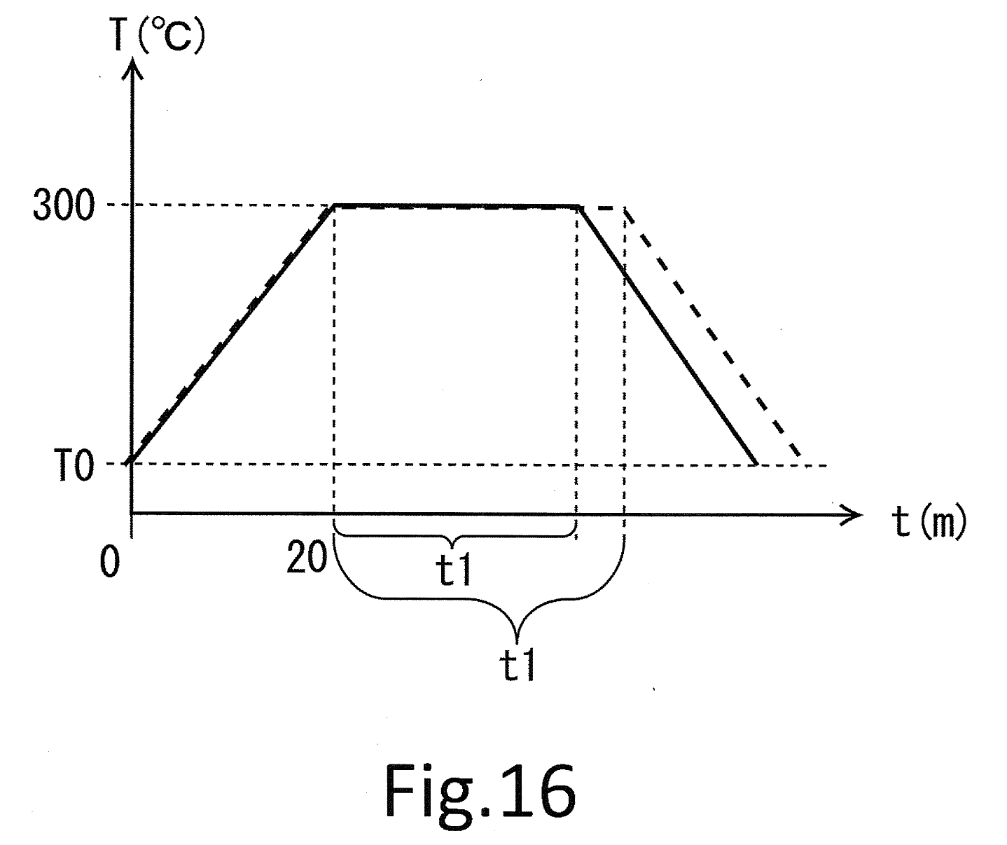

FIG. 16 is a graph illustrating the time-temperature conditions for the bonding of the fifth substrate E and the sixth substrate F together according to the method of manufacturing the semiconductor device 500 of this embodiment. The horizontal axis of the graph represents the time t (mm), and the vertical axis represents the temperature T (° C.). The solid lines represent the time/temperature of the upper heater plate 220, the dashed lines represent the time/temperature of the lower heater plate 230.

As FIG. 16 shows, the upper heater plate 220 and the lower heater plate 230 with their respective substrates mounted thereon are adhered to each other at room temperature T0 and are thereby bonded together. Then, the temperatures of the two heater plates 220 and 230 are raised from the room temperature T0 up to 300° C. in 20 minutes and are kept at 300° C. The temperature of the upper heater plate 220 is kept at 300° C. for a keeping time t1 of 45 minutes, and is then lowered down to the room temperature T0. The temperature of the lower heater plate 230 is kept at 300° C. for a keeping time t2 of 60 minutes, and is then lowered down to the room temperature T0. Both the temperature of the upper heater plate 220 and the temperature of the lower heater plate 230 are lowered down at the same rate.

This temperature-changing way of this embodiment allows a difference between the temperatures of the two substrates E and F to be left when the bonding material is solidified and the interface is fixed. Accordingly, this embodiment can have the same effects that are obtainable in the first embodiment.

Nevertheless, since the temperatures of the two heater plates 220 and 230 are always the same from the start of the temperature-raising until the temperatures of the two heater plates 220 and 230 are both kept, the temperature of the bonded interface can be controlled more easily than in the case of the first embodiment. In other words, the temperature of the bonded interface is not affected by the thicknesses of the substrates or the heat conductions of the substrates.

Note that the bonding in this embodiment can be performed with the insert layer described in the first modified example of the first embodiment.

The heat-treatment apparatuses used in the embodiments described above are apparatuses each of which clamps the substrates to be bonded with two heaters from above and from below.

There are various other methods of performing a heat treatment. For example, in the cases of the direct bonding and of the surface activated bonding, that is, in cases where the two substrates are adhered to each other with the forces acting from within the substrates before the heat treatment, plural sets of the adhered substrates can be treated together with heat, if necessary, by putting the plural sets of the adhered substrates in an ordinary diffusion furnace.

If a vertical-type furnace is used, the temperature gradient in the up-and-down directions can be controlled. Accordingly, for example, the temperature of the lower portions of the furnace can be made higher by placing the substrates with smaller thermal expansion coefficients at the lower positions in the furnace.

If a horizontal-type furnace is used, the convection in the furnace makes the temperature of the upper portion of the section higher automatically. Accordingly, in the case of a heat treatment using a horizontal furnace, the wafers are not placed vertically as in the ordinary cases but placed horizontally to cause the substrates with smaller thermal expansion coefficients to be positioned on the upper side.

In addition, the substrates and the epitaxial substrates used in the embodiments described above are made of Si, GaAs, and sapphire. Even if a Ge substrate is used, similar effects can be obtained as long as the substrates and the epitaxial substrates are made of a metal or a semiconductor material, for example. Ge has a relatively large thermal expansion coefficient of 77×10⁻⁶/K. Hence, if a Ge substrate is bonded to a substrate made of other materials, the temperature of the Ge substrate is set to be lower.

What is claimed is:

1. A method of manufacturing a semiconductor device comprising the steps of:
forming a first substrate, providing a semiconductor laminate body to support substrate,
adhering a second substrate to a surface of the first substrate in which the semiconductor laminate body, the second substrate having the second substrate having a thermal expansion coefficient different from the thermal expansion coefficient of the first substrate; and
bonding the first substrate and the second substrate by heating the first and second substrates while one of the substrates with a smaller thermal expansion coefficient is heated at a higher temperature than that of the other substrate.

2. The method of manufacturing a semiconductor device according to claim 1, wherein
the first substrate is a substrate obtained by providing the semiconductor laminate body to the support substrate, the semiconductor laminate body making GaN the main quality of the materials and the support substrate making sapphire the main quality of the materials, and the second substrate making a Si the main quality of the materials.

3. The method of manufacturing a semiconductor device according to claim 1, wherein
the heating method keeps the temperature of the substrate with the smaller thermal expansion coefficient higher than the temperature of the other substrate either among the first substrate and the second substrate, in a temperature-raising process.

4. The method of manufacturing a semiconductor device according to claim 3, wherein
the heating method keeps the same temperature of the first substrate and send the second substrate at least the first half of a constant-temperature-keeping processing a temperature-lowering process.

5. The method of manufacturing a semiconductor device according to claim 1, further comprising the steps of:
forming a first bonding layer, a second bonding layer, and a third bonding layer in this order between the first substrate and the second substrate; and
adhering the first substrate and the second substrate to each other with the first bonding layer, the second bonding layer, and the third bonding layer interposed therebetween, and heating the first substrate and the second substrate thus adhered.

6. The method of manufacturing a semiconductor device according to claim 5, wherein the heating step includes a step of lowering the temperatures of the first and second substrates while keeping the temperature of the substrate with the smaller thermal expansion coefficient higher than the temperature of the other substrate, after the first bonding layer and the second bonding layer are solidified and a bonding interface is fixed.

7. The method of manufacturing a semiconductor device according to claim 5, further comprising the steps of:
forming a first bonding layer, a second bonding layer, an insert layer, and a third bonding layer in this order between the first substrate and the second substrate; and
adhering the first substrate and the second substrate to each other with the first bonding layer, the second bonding layer, the insert layer, and the third bonding layer interposed therebetween, and heating the first substrate and the second substrate thus adhered.

8. The method of manufacturing a semiconductor device according to claim 7, wherein
the first bonding layer is made of Au,
the second bonding layer is made mainly of any one of In, Sn, AuSn, and InSn,
the third bonding layer is made of Au, and
the insert layer is made mainly of any one of Ti, Ni, and W.

9. The method of manufacturing a semiconductor device according to any one of claims 8, wherein the second bonding layer is formed by forming layers of In, Au, Ti, Pt, and Ti in this order from the second-principal-surface side of the semiconductor laminate body.

10. A method of manufacturing a semiconductor device comprising the steps of:
forming a first substrate by providing a a semiconductor laminate body to a support substrate, the semiconductor laminate making InGaAlP the main quality of the materials, and the support substrate making GaAs the main quality of the materials containing GaAs;
adhering a second substrate to the first substrate, the second substrate making GaP the main quality of the materials; and
bonding the first substrate and the second substrate by heating the first and second substrates with the second substrate heated at a temperature higher than that of the first substrate.

11. The method of manufacturing a semiconductor device according to claim 10, wherein
the heating method keeps the temperature of the substrate with the smaller thermal expansion coefficient higher than the temperature of the other substrate either among the first substrate and the second substrate, in a temperature-raising process.

12. The method of manufacturing a semiconductor device according to claim 11, wherein
the heating method keeps the same temperature of the first substrate and send the second substrate at least the first half of a constant-temperature-keeping processing a temperature-lowering process.

13. The method of manufacturing a semiconductor device according to claim 10, further comprising the steps of:
forming a first bonding layer, a second bonding layer, and a third bonding layer in this order between the first substrate and the second substrate; and
adhering the first substrate and the second substrate to each other with the first bonding layer, the second bonding layer, and the third bonding layer interposed therebetween, and heating the first substrate and the second substrate thus adhered.

14. The method of manufacturing a semiconductor device according to claim 13, wherein the heating step includes a step of lowering the temperatures of the first and second substrates while keeping the temperature of the substrate with the smaller thermal expansion coefficient higher than the temperature of the other substrate, after the first bonding layer and the second bonding layer are solidified and a bonding interface is fixed.

15. The method of manufacturing a semiconductor device according to claim 13, further comprising the steps of:
forming a first bonding layer, a second bonding layer, an insert layer, and a third bonding layer in this order between the first substrate and the second substrate; and
adhering the first substrate and the second substrate to each other with the first bonding layer, the second bonding layer, the insert layer, and the third bonding layer interposed therebetween, and heating the first substrate and the second substrate thus adhered.

16. The method of manufacturing a semiconductor device according to claim 15, wherein
the first bonding layer is made of Au,
the second bonding layer is made mainly of any one of In, Sn, AuSn, and InSn,
the third bonding layer is made of Au, and
the insert layer is made mainly of any one of Ti, Ni, and W.

17. The method of manufacturing a semiconductor device according to any one of claims 16, wherein the second bonding layer is formed by forming layers of In, Au, Ti, Pt, and Ti in this order from the second-principal-surface side of the semiconductor laminate body.
